(19) United States
(12) Patent Application Publication
(10) Pub. No.: US 2024/0395753 A1
(43) Pub. Date: Nov. 28, 2024

(54) SEMICONDUCTOR MEMORY DEVICE AND SEMICONDUCTOR PACKAGE INCLUDING THE SAME

(71) Applicant: Samsung Electronics Co., Ltd., Suwon-si (KR)

(72) Inventors: Bong geun Choi, Suwon-si (KR); Jisuk Kwon, Suwon-si (KR); Seokjae Lee, Suwon-si (KR)

(21) Appl. No.: 18/584,876

(22) Filed: Feb. 22, 2024

(30) Foreign Application Priority Data
May 26, 2023 (KR) 10-2023-0068646
Aug. 18, 2023 (KR) 10-2023-0108045

(51) Int. Cl. H01L 23/00; H01L 25/065; H10B 80/00

(52) U.S. Cl. CPC H01L 24/13; H01L 25/0652; H10B 80/00; H01L 2224/13023; H01L 2924/1431; H01L 2924/1436

(57) ABSTRACT

A semiconductor memory device includes a memory cell array, first to fourth I/O pads under the memory cell array and configured to connect with an external device, and first to fourth I/O driving modules between the memory cell array and the first to fourth I/O pads and configured to drive the first to fourth I/O pads, respectively. In a plan view, the first and second I/O driving modules are disposed symmetrically with respect to a first line extending in a first direction, the third and fourth I/O driving modules are disposed symmetrically with respect to the first line, the first and third I/O driving modules are disposed symmetrically with respect to a second line extending in a second direction crossing the first direction, and the second and fourth I/O driving modules are disposed symmetrically with respect to the second line.

### CROSS-REFERENCE TO RELATED APPLICATION

This application claims priority under 35 U.S.C. § 119 to Korean Patent Application No. 10-2023-0068646, filed on May 26, 2023, and to Korean Patent Application No. 10-2023-0108045, filed on Aug. 18, 2023, in the Korean Intellectual Property Office (KIPO), the contents of both of which are herein incorporated by reference in their entirety.

### BACKGROUND

### 1. Technical Field

Example embodiments relate generally to semiconductor integrated circuits, and more particularly to semiconductor memory devices, and semiconductor packages including the semiconductor memory devices.

### 2. Description of the Related Art

Semiconductor memory devices include volatile and nonvolatile memory devices. Volatile memory devices lose stored data when disconnected from power, and nonvolatile memory devices retain stored data when disconnected from power. Volatile memory devices may perform read and write operations at a higher speed than nonvolatile memory devices. Nonvolatile memory devices may be used to store data that needs to be retained regardless of whether power is provided.

To improve input/output (I/O) performance of semiconductor memory devices, semiconductor memory devices including multiple I/O pads for exchanging signals with external devices have been researched. In addition, various technologies have been researched to efficiently design and manufacture such semiconductor memory devices.

### SUMMARY

At least one example embodiment of the present disclosure provides a semiconductor memory device capable of having advantages in terms of power, performance, and area (PPA).

At least one example embodiment of the present disclosure provides a semiconductor package including the semiconductor memory device.

According to example embodiments, a semiconductor memory device includes a memory cell array, first, second, third, and fourth input/output (I/O) pads, and first, second, third, and fourth I/O driving modules. The first, second, third, and fourth I/O pads are under the memory cell array, and configured to electrically connect the memory cell array with an external device. The first, second, third, and fourth I/O driving modules are between the memory cell array and the first, second, third, and fourth I/O pads, and drive the first, second, third, and fourth I/O pads, respectively. In a plan view, the first and second I/O driving modules are disposed symmetrically with respect to a first line extending in a first direction, the third and fourth I/O driving modules are disposed symmetrically with respect to the first line, the first and third I/O driving modules are disposed symmetrically with respect to a second line extending in a second direction crossing the first direction, and the second and fourth I/O driving modules are disposed symmetrically with respect to the second line.

According to example embodiments, a semiconductor package includes a plurality of semiconductor memory devices that are sequentially stacked in a vertical direction. Each of the plurality of semiconductor memory devices includes a memory cell array, first, second, third, and fourth input/output (I/O) pads, and first, second, third, and fourth I/O driving modules. The first, second, third, and fourth I/O pads are under the memory cell array, and configured to electrically connect the memory cell array with an external device. The first, second, third, and fourth I/O driving modules are between the memory cell array and the first, second, third, and fourth I/O pads, and drive the first, second, third, and fourth I/O pads, respectively. In a plan view, the first and second I/O driving modules are disposed symmetrically with respect to a first line extending in a first direction, the third and fourth I/O driving modules are disposed symmetrically with respect to the first line, the first and third I/O driving modules are disposed symmetrically with respect to a second line extending in a second direction crossing the first direction, and the second and fourth I/O driving modules are disposed symmetrically with respect to the second line.

According to example embodiments, a semiconductor memory device includes a memory cell array, first, second, third, and fourth input/output (I/O) pads, first and second power pads, and first, second, third, and fourth I/O driving modules. The first, second, third, and fourth I/O pads are under the memory cell array, and configured to electrically connect the memory cell array with an external device. The first and second power pads are under the memory cell array, and provide a power supply voltage and a ground voltage. The first, second, third, and fourth I/O driving modules are between the memory cell array and the first to fourth I/O pads and between the memory cell array and the first and second power pads, and configured to drive the first, second, third, and fourth I/O pads, respectively. In a plan view, the first and second I/O driving modules are disposed symmetrically with respect to a first line extending in a first direction, the third and fourth I/O driving modules are disposed symmetrically with respect to the first line, the first and third I/O driving modules are disposed symmetrically with respect to a second line extending in a second direction crossing the first direction, and the second and fourth I/O driving modules are disposed symmetrically with respect to the second line. In the plan view, the first and third I/O pads are arranged along the first direction, the first and second power pads are arranged along the first direction, the second and fourth I/O pads are arranged along the first direction, the first I/O pad, the first power pad, and the second I/O pad are arranged along the second direction, and the third I/O pad, the second power pad, and the fourth I/O pad are arranged along the second direction. The first I/O driving module overlaps the first I/O pad and a first portion of the first power pad, the second I/O driving module overlaps the second I/O pad and a second portion of the first power pad, the third I/O driving module overlaps the third I/O pad and a first portion of the second power pad, and the fourth I/O driving module overlaps the fourth I/O pad and a second portion of the second power pad. The first, second, third, and fourth I/O driving modules include first, second, third, and fourth logic circuits, respectively. The first, second, third, and fourth I/O driving modules include first, second, third, and fourth empty spaces, respectively, in which the first, second, third, and fourth logic circuits are not disposed. The first to fourth empty spaces are adjacent to the first and second lines. The first to fourth empty spaces are shared by the first to fourth I/O driving modules.

In the semiconductor memory device and the semiconductor package according to example embodiments, four adjacent I/O driving modules may be arranged in the common-centroid structure, and four adjacent I/O driving modules may be disposed such that the empty spaces in which the logic circuits are not placed within the I/O driving modules are gathered near the center. The relatively large empty space near the center may be shared by four I/O drive modules. For example, the common control logic circuit and/or the power capacitors that are commonly used by the four I/O driving modules may be placed in the relatively large empty space. Accordingly, power consumption may be reduced, area may be reduced, performance may be improved, and mutual shielding between the signal wires may be implemented.

### BRIEF DESCRIPTION OF THE DRAWINGS

Illustrative, non-limiting example embodiments will be more clearly understood from the following detailed description taken in conjunction with the accompanying drawings.

FIG. 1 is a cross-sectional view of a semiconductor memory device according to example embodiments.

FIGS. 2, 3, 4, and 5 are plan views of a semiconductor memory device according to example embodiments.

FIGS. 6 and 7 are diagrams illustrating examples of I/O driving module groups of FIGS. 3 and 5.

FIGS. 8A, 8B, and 8C are diagrams for describing an operation of an I/O driving module group of FIG. 7.

FIGS. 9 and 10 are diagrams illustrating examples of I/O driving module groups of FIGS. 3 and 5.

FIGS. 11A, 11B, 11C, 11D, 12A, 12B, 12C, and 12D are diagrams illustrating examples of I/O driving module groups of FIGS. 3 and 5.

FIG. 13 is a cross-sectional view of a semiconductor memory device according to example embodiments.

FIGS. 14, 15A, and 15B are plan views of a semiconductor memory device according to example embodiments.

FIG. 16 is a block diagram illustrating an example of a semiconductor memory device according to example embodiments.

FIG. 17 is a block diagram illustrating a memory system including a semiconductor memory device according to example embodiments.

FIGS. 18, 19, and 20 are diagrams illustrating a semiconductor package according to example embodiments.

### DETAILED DESCRIPTION OF THE EMBODIMENTS

Various example embodiments will be described more fully with reference to the accompanying drawings, in which embodiments are shown. The present disclosure may, however, be embodied in many different forms and should not be construed as limited to the embodiments set forth herein. Like reference numerals refer to like elements throughout this application.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise.

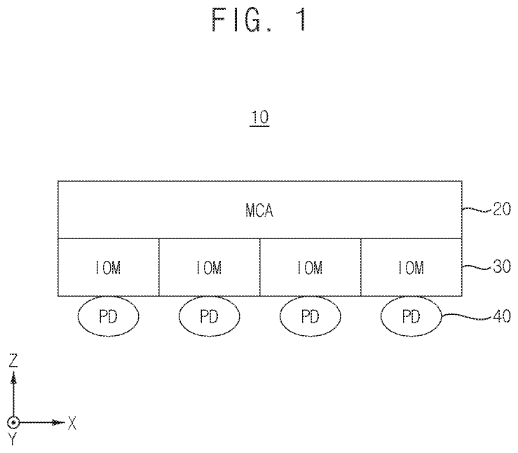

FIG. 1 is a cross-sectional view of a semiconductor memory device according to example embodiments.

In FIG. 1, two directions that are each parallel or substantially parallel to a first surface (e.g., a top surface) of a semiconductor substrate and perpendicular to each other are referred to as a first direction X (e.g., an X-axis direction) and a second direction Y (e.g., a Y-axis direction). In addition, a direction vertical or substantially vertical to the first surface of the semiconductor substrate is referred to as a third direction Z (e.g., a Z-axis direction). For example, the first and second directions X and Y may be perpendicular or substantially perpendicular to each other. In addition, the third direction Z may be perpendicular or substantially perpendicular to both the first and second directions X and Y. Further, a direction indicated by an arrow in the figures and a reverse direction thereof are considered as the same direction. The definition of the first, second and third directions X, Y and Z are same in the subsequent figures.

Referring to FIG. 1, a semiconductor memory device 10 includes a memory cell array (MCA) 20, a plurality of input/output (I/O) driving modules (IOMs) 30, and a plurality of pads (PDs) 40.

The memory cell array 20 includes a plurality of memory cells, and stores data. Although not illustrated in detail, the memory cell array 20 may be disposed and/or formed on a semiconductor substrate.

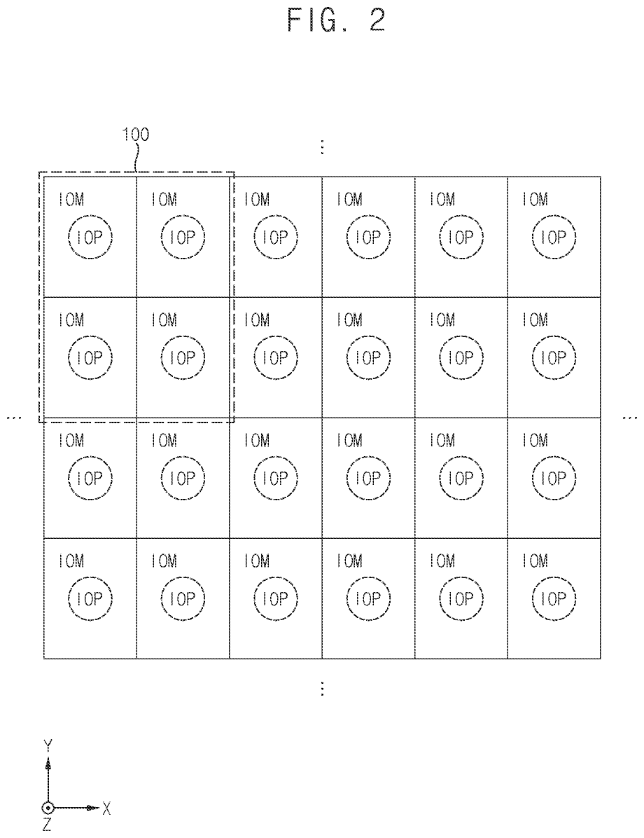

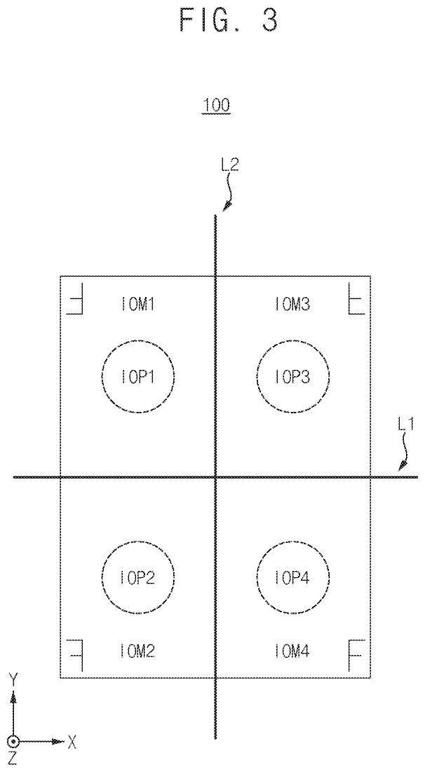

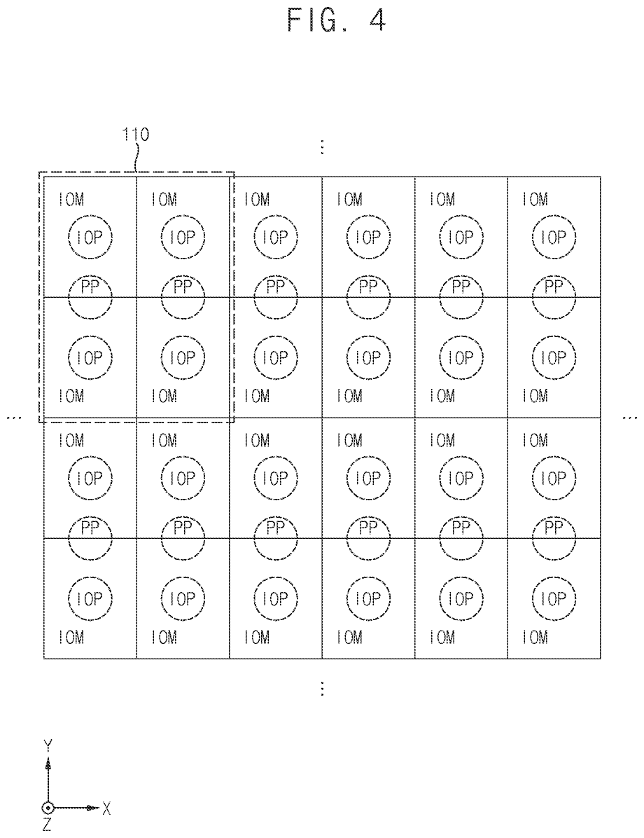

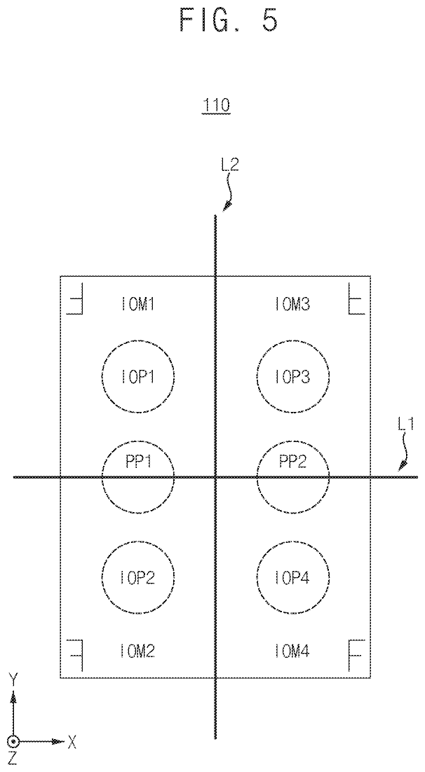

The plurality of pads 40 are disposed under or below the memory cell array 20, and are formed for physical connection and/or electrical connection with an external device. For example, the semiconductor memory device 10 may be mounted on an external printed circuit board (PCB) through the plurality of pads 40. For example, as will be described with reference to FIGS. 2 and 3, the plurality of pads 40 may include a plurality of I/O pads (IOPs) for exchanging a data signal, etc., with the external device. For example, as will be described with reference to FIGS. 4 and 5, the plurality of pads 40 may further include a plurality of power pads (PPs) for providing a power supply voltage, a ground voltage, etc., to the semiconductor memory device 10.

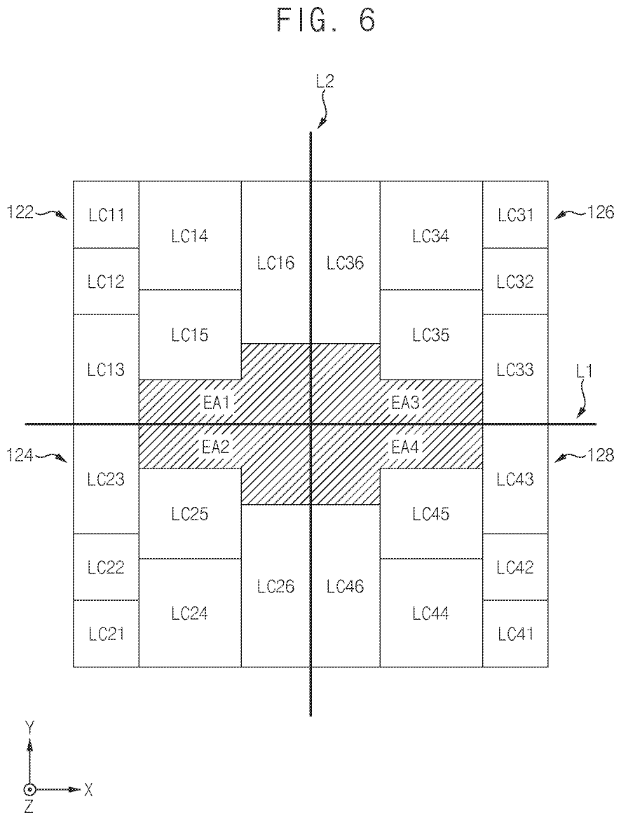

The plurality of I/O driving modules 30 are disposed between the memory cell array 20 and the plurality of pads 40, and are formed to drive the plurality of I/O pads among the plurality of pads 40. For example, one I/O driving module may drive one I/O pad, and the number of the plurality of I/O driving modules 30 may be equal to the number of the plurality of I/O pads. For example, as will be described later with reference to FIG. 6, each of the plurality of I/O driving modules 30 may include a plurality of logic circuits (LC) for driving the I/O pad. For example, the plurality of I/O driving modules 30 may be electrically connected to the memory cell array 20, and may include components for driving the plurality of pads 40 among peripheral circuits that control an operation of the memory cell array 20.

In the semiconductor memory device 10 according to example embodiments, four adjacent I/O driving modules among the plurality of I/O driving modules 30 may be arranged in a common-centroid structure (e.g., a top-bottom and left-right symmetrical structure), which will be described later.

Although FIG. 1 illustrates that the plurality of pads 40 are disposed at the bottom of the semiconductor memory device 10 and the plurality of I/O driving modules 30 and the memory cell array 20 are disposed on the plurality of pads 40, example embodiments are not limited thereto. For example, when the semiconductor memory device 10 is turned over during the manufacturing process, the plurality of pads 40 may be disposed at the top of the semiconductor memory device 10, and the plurality of I/O driving modules 30 and the memory cell array 20 may be disposed under the pads 40. In some example embodiments, the memory cell array 20 and the plurality of I/O driving modules 30 may be disposed on the same plane.

FIGS. 2, 3, 4, and 5 are plan views of a semiconductor memory device according to example embodiments.

Referring to FIG. 2, an example of an arrangement of a plurality of I/O pads IOP and a plurality of I/O driving modules IOM included in the semiconductor memory device 10 of FIG. 1 is illustrated in a plan view. For convenience of illustration, the memory cell array 20 in FIG. 1 is omitted.

The plurality of I/O pads IOP may be arranged continuously and/or regularly along the first direction X and the second direction Y, and may be arranged in a two-dimensional (2D) matrix formation. For example, FIG. 2 illustrates an example where twenty-four I/O pads IOP are arranged six along the first direction X and four along the second direction Y, e.g., where twenty-four I/O pads IOP are arranged in four rows and six columns, but example embodiments are not limited thereto. For example, I/O pads IOP included in the same row may be arranged to be spaced apart by a certain distance (e.g., a first distance), and I/O pads IOP included in the same column may be arranged to be spaced apart by a certain distance (e.g., a second distance).

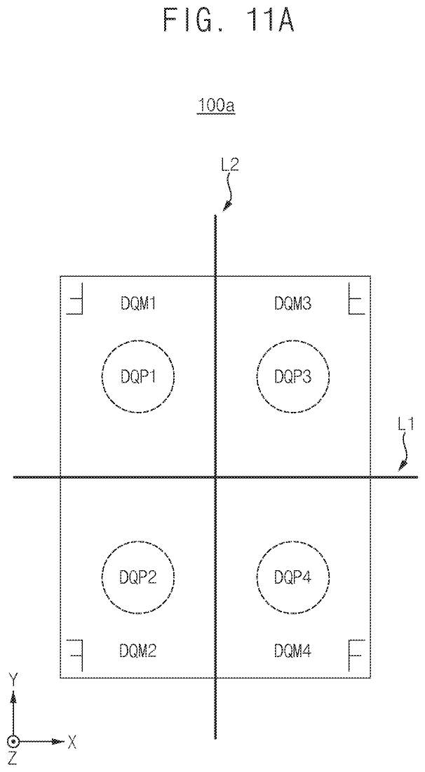

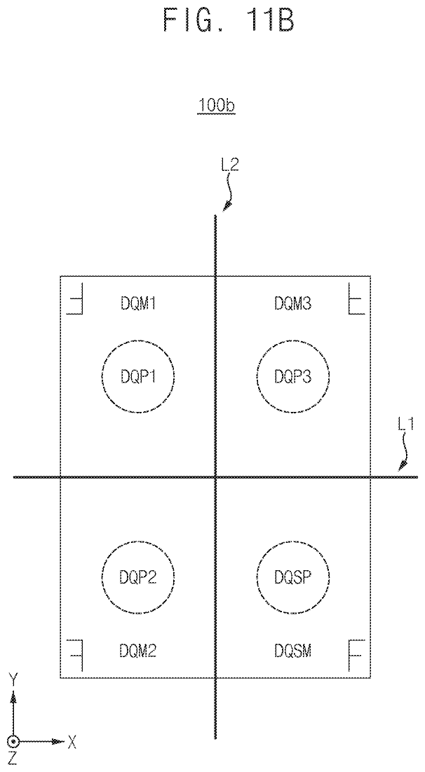

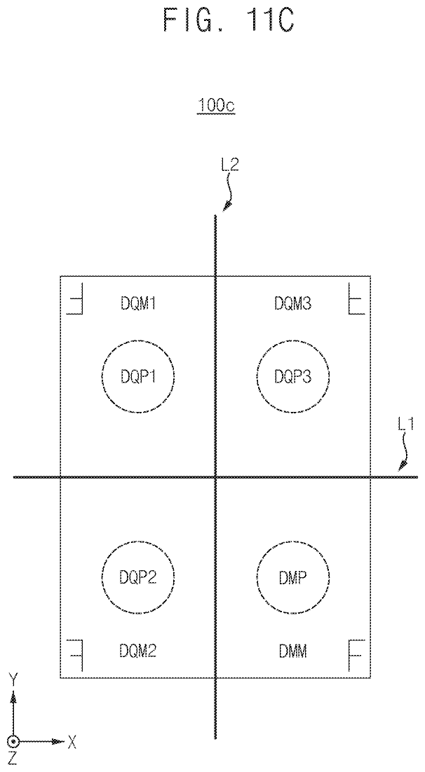

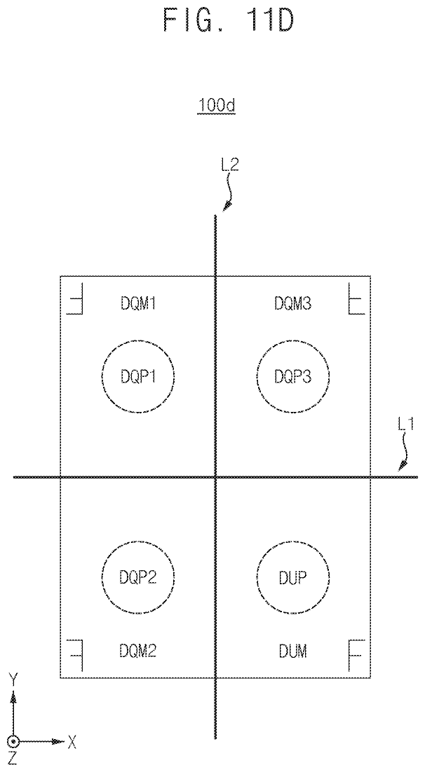

In some example embodiments, as will be described with reference to FIG. 11, the plurality of I/O pads IOP may include a data pad that inputs and outputs a data signal DQ, a data strobe pad that inputs and outputs a data strobe signal DQS, a data mask pad that inputs and outputs a data mask signal DM, and a dummy pad that does not input or output a signal or inputs or outputs a signal unrelated to an operation of the semiconductor memory device.

As with the plurality of I/O pads IOP, the plurality of I/O driving modules IOM may also be arranged continuously and/or regularly along the first direction X and the second direction Y. For example, FIG. 2 illustrates an example where twenty-four I/O driving modules IOM are arranged six along the first direction X and four along the second direction Y. In other words, each of the plurality of I/O driving modules IOM may be disposed to correspond to and/or overlap a respective one of the plurality of I/O pads IOP. One I/O pad and one I/O driving module that are arranged to correspond to and/or overlap each other may form one pad-module pair that is electrically connected to each other. For example, the I/O pad IOP disposed in a first row and a first column may be driven by the I/O driving module IOM that is disposed in a first row and a first column and overlaps the I/O pad IOP in the first row and the first column.

In some example embodiments, each of the plurality of I/O driving modules IOM may include various logic circuits required to drive the plurality of I/O pads IOP, e.g., a pull-up circuit, a pull-down circuit, a multiplexer, an output driver, an input buffer, an electrostatic discharge (ESD) protection circuit, etc.

Among the plurality of I/O driving modules IOM, four adjacent I/O driving modules IOM in the first direction X and the second direction Y may form one I/O driving module group 100. Four I/O driving modules IOM included in one I/O driving module group 100 may be arranged in the common-centroid structure.

Referring to FIG. 3, an example of the I/O driving module group 100 in FIG. 2 is illustrated.

The I/O driving module group 100 may include a first I/O driving module IOM1, a second I/O driving module IOM2, a third I/O driving module IOM3, and a fourth I/O driving module IOM4.

In a plan view or on a plane, the first, second, third and fourth I/O driving modules IOM1, IOM2, IOM3, and IOM4 may be arranged in a 2*2 structure and may be arranged in the common-centroid structure. For example, the first I/O driving module IOM1 and the second I/O driving module IOM2 may be disposed symmetrically with respect to a first line L1 extending in the first direction X. The third I/O driving module IOM3 and the fourth I/O driving module IOM4 may be disposed symmetrically with respect to the first line L1. The first I/O driving module IOM1 and the third I/O driving module IOM3 may be disposed symmetrically with respect to a second line L2 extending in the second direction Y. The second I/O driving module IOM2 and the fourth I/O driving module IOM4 may be disposed symmetrically with respect to the second line L2. The ‘F’ mark at the corner of each of the first, second, third, and fourth I/O driving modules IOM1, IOM2, IOM3, and IOM4 may indicate a symmetrical relationship between adjacent I/O driving modules.

The plurality of I/O pads IOP may include a first I/O pad IOP1, a second I/O pad IOP2, a third I/O pad IOP3, and a fourth I/O pad IOP4.

In a plan view, the first, second, third, and fourth I/O pads IOP1, IOP2, IOP3, and IOP4 may be arranged in the 2*2 structure. For example, the first I/O pad IOP1 and the third I/O pad IOP3 may be arranged to be spaced apart by a first distance along the first direction X within a first row. The second I/O pad IOP2 and the fourth I/O pad IOP4 may be arranged to be spaced apart by the first distance along the first direction X within a second row. The first I/O pad IOP1 and the second I/O pad IOP2 may be arranged to be spaced apart by a second distance along the second direction Y within a first column. The third I/O pad IOP3 and the fourth I/O pad IOP4 may be arranged to be spaced apart by the second distance along the second direction Y within a second column. In some example embodiments, the first distance and the second distance may be equal to or different from each other.

The first, second, third, and fourth I/O driving modules IOM1, IOM2, IOM3, and IOM4 may drive the first, second, third, and fourth I/O pads IOP1, IOP2, IOP3, and IOP4, respectively. The first, second, third, and fourth I/O driving modules IOM1, IOM2, IOM3, and IOM4 may be disposed to overlap the first, second, third, and fourth I/O pads IOP1, IOP2, IOP3, and IOP4, respectively. For example, the first I/O driving module IOM1 that drives the first I/O pad IOP1 may be disposed to overlap the first I/O pad IOP1. For example, a center of the first I/O pad IOP1 and a center of the first I/O driving module IOM1 may overlap, but example embodiments are not limited thereto.

The first line L1 and the second line L2 may be virtual lines. For example, the first line L1 may be formed to pass between the first and second I/O pads IOP1 and IOP2 and between the third and fourth I/O pads IOP3 and IOP4. For example, the second line L2 may be formed to pass between the first and third I/O pads IOP1 and IOP3 and between the second and fourth I/O pads IOP2 and IOP4.

Referring to FIG. 4, an example of an arrangement of a plurality of I/O pads IOP, a plurality of power pads PP and a plurality of I/O driving modules IOM included in the semiconductor memory device 10 of FIG. 1 is illustrated in a plan view.

An example of FIG. 4 may be substantially the same as the example of FIG. 2, except that the plurality of power pads PP are further included in the example of FIG. 4. The descriptions repeated with FIG. 2 will be omitted.

The plurality of power pads PP may be disposed between the plurality of I/O pads IOP. For example, power pads PP in a first row may be disposed between I/O pads IOP in a first row and I/O pads IOP in a second row, and power pads PP in a second row may be disposed between I/O pads IOP in a third row and I/O pads IOP in a fourth row. In other words, one row of power pads PP may be disposed to correspond to two rows of I/O pads IOP, but example embodiments are not limited thereto.

In some example embodiments, the plurality of power pads PP may include a power pad for providing a power supply voltage and a ground pad for providing a ground voltage.

Each of the plurality of I/O driving modules IOM may be disposed to correspond to and/or overlap a respective one of the plurality of I/O pads IOP, and may be disposed to correspond to and/or overlap a portion of a respective one of the plurality of power pads PP. Among the plurality of I/O driving modules IOM, four adjacent I/O driving modules IOM in the first direction X and the second direction Y may form one I/O driving module group 110. Four I/O driving modules IOM included in one I/O driving module group 110 may be arranged in the common-centroid structure.

Referring to FIG. 5, an example of the I/O driving module group 110 in FIG. 4 is illustrated.

An example of FIG. 5 may be substantially the same as the example of FIG. 3, except that first and second power pads PP1 and PP2 are further included in the example of FIG. 5. The descriptions repeated with FIG. 3 will be omitted.

In a plan view, the first and second power pads PP1 and PP2 may be disposed between the first, second, third, and fourth I/O pads IOP1, IOP2, IOP3, and IOP4. For example, the first power pad PP1 may be disposed between the first I/O pad IOP1 and the second I/O pad IOP2. The second power pad PP2 may be disposed between the third I/O pad IOP3 and the fourth I/O pad IOP4.

In a plan view, the first power pad PP1 and the second power pad PP2 may be arranged along the first direction X. The first I/O pad IOP1, the first power pad PP1 and the second I/O pad IOP2 may be arranged along the second direction Y. The third I/O pad IOP3, the second power pad PP2 and the fourth I/O pad IOP4 may be arranged along the second direction Y.

The first I/O driving module IOM1 may be disposed to overlap the first I/O pad IOP1 and a first portion of the first power pad PP1. The second I/O driving module IOM2 may be disposed to overlap the second I/O pad IOP2 and a second portion of the first power pad PP1. The third I/O driving module IOM3 may be disposed to overlap the third I/O pad IOP3 and a first portion of the second power pad PP2. The fourth I/O driving module IOM4 may be disposed to overlap the fourth I/O pad IOP4 and a second portion of the second power pad PP2.

As described with reference to FIGS. 2, 3, 4, and 5, when the first, second, third, and fourth I/O driving modules IOM1, IOM2, IOM3, and IOM4 are arranged in the common-centroid structure, the first, second, third, and fourth I/O driving modules IOM1, IOM2, IOM3, and IOM4 may share and utilize empty spaces inside the first, second, third, and fourth I/O driving modules IOM1, IOM2, IOM3, and IOM4. In addition, as described with reference to FIGS. 4 and 5, when the first, second, third, and fourth I/O driving modules IOM1, IOM2, IOM3, and IOM4 are to be arranged, areas (e.g., I/O pad areas) on the first, second, third, and fourth I/O pads may be utilized, and areas (e.g., power pad areas) on the first and second power pads PP1 and PP2 disposed between the first, second, third, and fourth I/O pads IOP1, IOP2, IOP3, and IOP4 may also be used additionally.

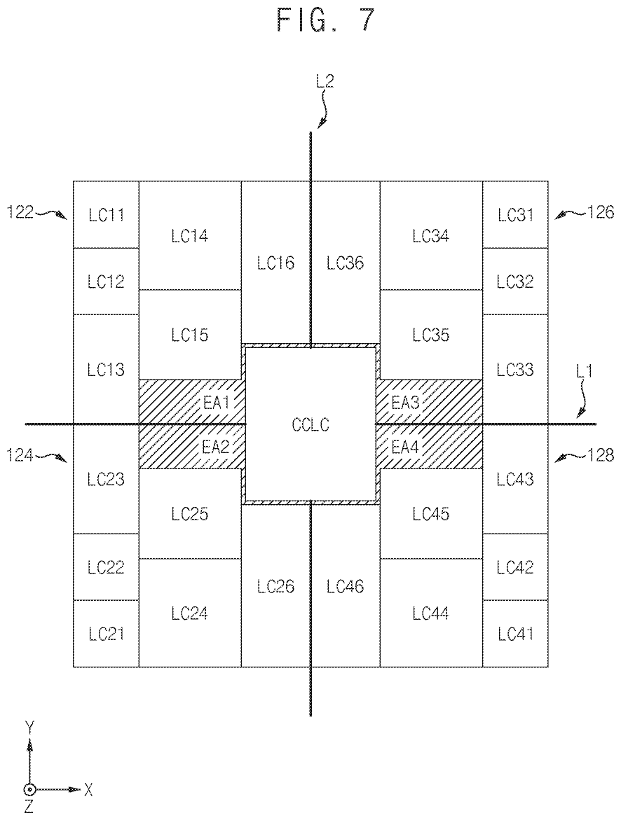

FIGS. 6 and 7 are diagrams illustrating examples of I/O driving module groups of FIGS. 3 and 5, respectively.

Referring to FIG. 6, an example of a layout of a first I/O driving module 122, a second I/O driving module 124, a third I/O driving module 126, and a fourth I/O driving module 128, which correspond to the first, second, third, and fourth I/O driving modules IOM1, IOM2, IOM3, and IOM4 in FIGS. 3 and 5, is illustrated.

The first I/O driving module 122 may include first logic circuits LC11, LC12, LC13, LC14, LC15, and LC16. The second I/O driving module 124 may include second logic circuits LC21, LC22, LC23, LC24, LC25, and LC26. The third I/O driving module 126 may include third logic circuits LC31, LC32, LC33, LC34, LC35, and LC36. The fourth I/O driving module 128 may include fourth logic circuits LC41, LC42, LC43, LC44, LC45, and LC46.

The first, second, third, and fourth I/O driving modules 122, 124, 126, and 128 may be obtained by substantially the same design and/or manufacturing process, and thus the first, second, third, and fourth I/O driving modules 122, 124, 126, and 128 may have substantially the same structure/arrangement and may perform substantially the same function/operation. For example, the first logic circuit LC11 included in the first I/O driving module 122, the second logic circuit LC21 included in the second I/O driving module 124, the third logic circuit LC31 included in the third I/O driving module 126, and the fourth logic circuit LC41 included in the fourth I/O driving module 128 may be substantially the same circuit. In addition, the first logic circuits LC12, LC13, LC14, LC15, and LC16 included in the first I/O driving module 122 may be substantially the same circuit as the second logic circuits LC22, LC23, LC24, LC25, and LC26 included in the second I/O driving module 124, respectively, the third logic circuits LC32, LC33, LC34, LC35, and LC36 included in the third I/O driving module 126, respectively, and the fourth logic circuit LC42, LC43, LC44, LC45, and LC46 included in the fourth I/O driving module 128, respectively.

In a plan view, the first, second, third, and fourth I/O driving modules 122, 124, 126, and 128 may be arranged in the common-centroid structure, and thus the first logic circuits LC11, LC12, LC13, LC14, LC15, and LC16, the second logic circuits LC21, LC22, LC23, LC24, LC25, and LC26, the third logic circuits LC31, LC32, LC33, LC34, LC35, and LC36, and the fourth logic circuits LC41, LC42, LC43, LC44, LC45, and LC46 may also be arranged in the common-centroid structure. For example, an arrangement of the first logic circuits LC11, LC12, LC13, LC14, LC15, and LC16 and an arrangement of the second logic circuits LC21, LC22, LC23, LC24, LC25, and LC26 may be symmetrically with respect to the first line L1 An arrangement of the third logic circuits LC31, LC32, LC33, LC34, LC35, and LC36 and an arrangement of the fourth logic circuits LC41, LC42, LC43, LC44, LC45, and LC46 may be symmetrically with respect to the first line L1, The arrangement of the first logic circuits LC11, LC12, LC13, LC14, LC15, and LC16 and the arrangement of the third logic circuits LC31, LC32, LC33, LC34, LC35, and LC36 may be symmetrically with respect to the second line L2. The arrangement of the second logic circuits LC21, LC22, LC23, LC24, LC25, and LC26 and the arrangement of the fourth logic circuits LC41, LC42, LC43, LC44, LC45, and LC46 may be symmetrically with respect to the second line L2.

The first I/O driving module 122 may include a first empty space (or area or region) EA1 in which the first logic circuits LC11, LC12, LC13, LC14, LC15, and LC16 are not disposed. The second I/O driving module 124 may include a second empty space EA2 in which the second logic circuits LC21, LC22, LC23, LC24, LC25, and LC26 are not disposed. The third I/O driving module 126 may include a third empty space EA3 in which the third logic circuits LC31, LC32, LC33, LC34, LC35, and LC36 are not disposed. The fourth I/O driving module 128 may include a fourth empty space EA4 in which the fourth logic circuits LC41, LC42, LC43, LC44, LC45, and LC46 are not disposed. The first, second, third, and fourth empty spaces EA1, EA2, EA3, and EA4 may be shared by the first, second, third and fourth I/O driving modules 122, 124, 126 and 128. For example, the first, second, third, and fourth empty spaces EA1, EA2, EA3, and EA4 may be adjacent to one another.

When the first, second, third, and fourth I/O driving modules 122, 124, 126, and 128 are arranged in the common-centroid structure, the first, second, third, and fourth empty spaces EA1, EA2, EA3, and EA4 may be combined to form a wider (or merged or larger) empty space, and a logic circuit required for all of the first, second, third, and fourth I/O driving modules 122, 124, 126, and 128 may be placed in the wider empty space. For example, the first, second, third, and fourth I/O driving modules 122, 124, 126, and 128 may be arranged such that the first, second, third, and fourth empty spaces EA1, EA2, EA3, and EA4 are gathered near the center. For example, the first, second, third, and fourth empty spaces EA1, EA2, EA3, and EA4 may be formed adjacent to the first and second lines L1 and L2.

Referring to FIG. 7, an example of utilizing the first, second, third, and fourth empty spaces EA1, EA2, EA3, and EA4 in FIG. 6 is illustrated. The descriptions repeated with FIG. 6 will be omitted.

The semiconductor memory device according to example embodiments may further include a common control logic circuit CCLC. The common control logic circuit CCLC may be disposed in at least a portion of the first, second, third, and fourth empty spaces EA1, EA2, EA3, and EA4, and may commonly control all of the first, second, third, and fourth I/O driving modules 122, 124, 126, and 128. For example, the common control logic circuit CCLC may commonly control at least some of the first logic circuits LC11, LC12, LC13, LC14, LC15, and LC16, at least some of the second logic circuits LC21, LC22, LC23, LC24, LC25, and LC26, at least some of the third logic circuits LC31, LC32, LC33, LC34, LC35, and LC36, and at least some of the fourth logic circuits LC41, LC42, LC43, LC44, LC45, and LC46.

The common control logic circuit CCLC may be a component for controlling all of the first, second, third, and fourth I/O driving modules 122, 124, 126, and 128, and thus may be disposed to correspond to all of the first, second, third, and fourth empty spaces EA1, EA2, EA3, and EA4. For example, the common control logic circuit CCLC may be disposed to correspond to an intersection of the first and second lines L1 and L2. For example, the common control logic circuit CCLC may include a signal repeater, a clock tree repeater, and/or the like.

When the common control logic circuit CCLC that controls all of four I/O driving modules is provided according to example embodiments, four I/O driving modules may be efficiently controlled with a smaller active area and less power consumption, as compared with a case where each of four I/O driving modules has a control logic circuit. In addition, when the first, second, third, and fourth I/O driving modules 122, 124, 126, and 128 are arranged in the common-centroid structure, the signal characteristic and performance may be improved and/or enhanced.

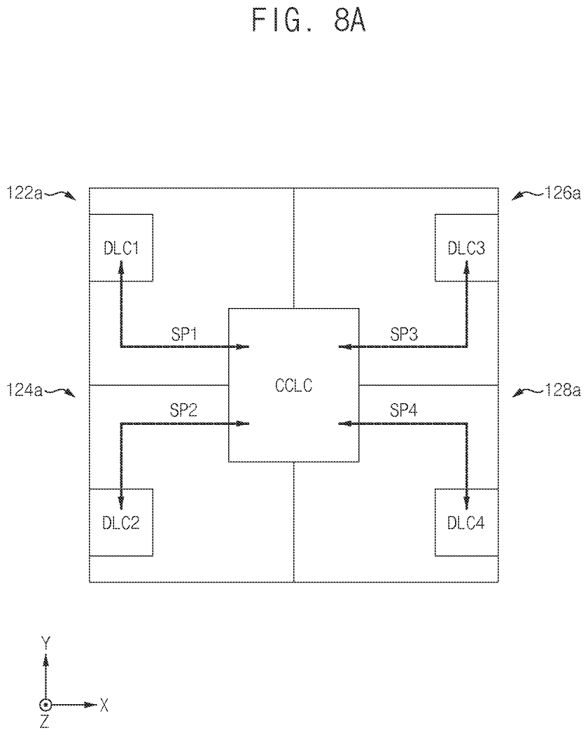

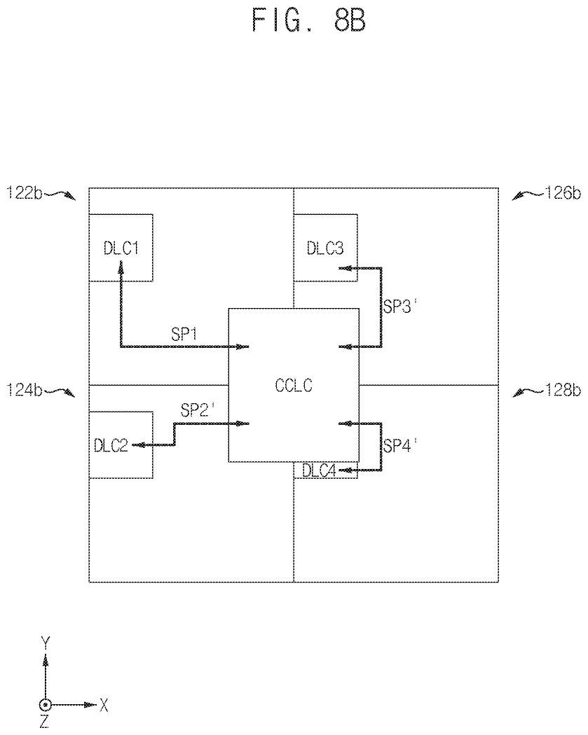

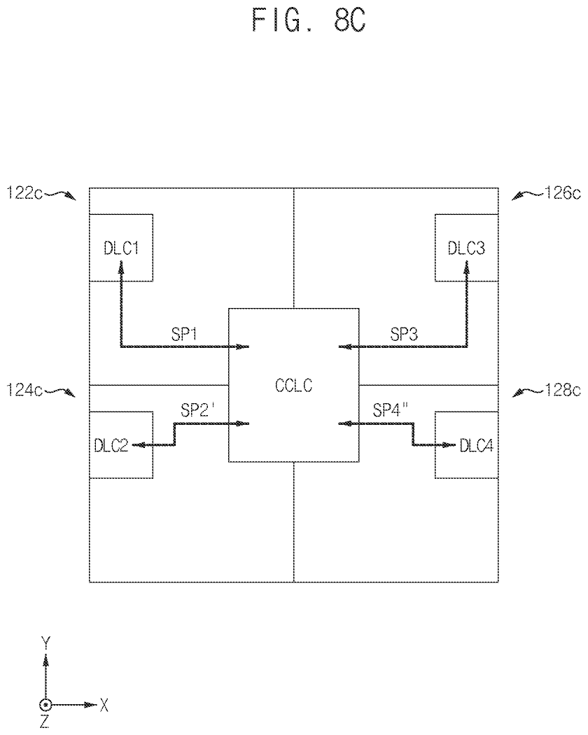

FIGS. 8A, 8B, and 8C are diagrams for describing an operation of an I/O driving module group of FIG. 7.

Referring to FIG. 8A, signal characteristics are illustrated when first, second, third and fourth I/O driving modules 122a, 124a, 126a, and 128a are arranged in the common-centroid structure according to example embodiments and when the common control logic circuit CCLC is placed in the empty space near the center.

The first I/O driving module 122a may include a first destination logic circuit DLC1, the second I/O driving module 124a may include a second destination logic circuit DLC2, the third I/O driving module 126a may include a third destination logic circuit DLC3, and the fourth I/O driving module 128a may include a fourth destination logic circuit DLC4. The first, second, third, and fourth destination logic circuits DLC1, DLC2, DLC3, and DLC4 may be substantially the same circuit. For example, the first, second, third, and fourth logic circuits LC12, LC22, LC32, and LC42 in FIG. 7 may correspond to the first, second, third, and fourth destination logic circuits DLC1, DLC2, DLC3, and DLC4, respectively.

When the first, second, third, and fourth I/O driving modules 122a, 124a, 126a, and 128a are operating or driven, the common control logic circuit CCLC may operate as a signal source, and the first, second, third, and fourth destination logic circuits DLC1, DLC2, DLC3, and DLC4 may operate as signal destinations. In an example of FIG. 8A, a length of a first signal path SP1 from the common control logic circuit CCLC to the first destination logic circuit DLC1, a length of a second signal path SP2 from the common control logic circuit CCLC to the second destination logic circuit DLC2, a length of a third signal path SP3 from the common control logic circuit CCLC to the third destination logic circuit DLC3, and a length of a fourth signal path SP4 from the common control logic circuit CCLC to the fourth destination logic circuit DLC4 may all be substantially the same as each other. Accordingly, all of the first, second, third, and fourth I/O driving modules 122a, 124a, 126a, and 128a may have the same timing skew and the symmetric signal characteristics, and thus the operation performance may be improved.

Referring to FIG. 8B, signal characteristics are illustrated when first, second, third, and fourth I/O driving modules 122b, 124b, 126b, and 128b are arranged in an asymmetric structure. The descriptions repeated with FIG. 8A will be omitted.

In an example of FIG. 8B, even though the common control logic circuit CCLC is placed near the center, a length of a first signal path SP1 from the common control logic circuit CCLC to the first destination logic circuit DLC1, a length of a second signal path SP2′ from the common control logic circuit CCLC to the second destination logic circuit DLC2, a length of a third signal path SP3′ from the common control logic circuit CCLC to the third destination logic circuit DLC3, and a length of a fourth signal path SP4′ from the common control logic circuit CCLC to the fourth destination logic circuit DLC4 may be different from each other. Therefore, all of the first, second, third, and fourth I/O driving modules 122b, 124b, 126b, and 128b may not have the symmetric signal characteristics.

Referring to FIG. 8C, signal characteristics are illustrated when first, second, third, and fourth I/O driving modules 122c, 124c, 126c, and 128c are arranged in a left-right symmetrical structure. The descriptions repeated with FIG. 8A will be omitted.

In an example of FIG. 8C, when the common control logic circuit CCLC is placed near the center, a length of a first signal path SP1 from the common control logic circuit CCLC to the first destination logic circuit DLC1, and a length of a third signal path SP3 from the common control logic circuit CCLC to the third destination logic circuit DLC3 may be substantially the same as each other, and thus the first and third I/O driving modules 122c and 126c may have the symmetric signal characteristics. In addition, a length of a second signal path SP2′ from the common control logic circuit CCLC to the second destination logic circuit DLC2, and a length of a fourth signal path SP4″ from the common control logic circuit CCLC to the fourth destination logic circuit DLC4 may be substantially the same as each other, and thus the second and fourth I/O driving modules 124c and 128c may have the symmetric signal characteristics. However, the lengths of the first and third signal paths SP1 and SP3, and the lengths of the second and fourth signal paths SP2′ and SP4″ may be different from each other, and thus all of the first, second, third, and fourth I/O driving modules 122c, 124c, 126c, and 128c may not have the symmetric signal characteristics.

Although not illustrated in detail, when first, second, third, and fourth I/O driving modules are arranged in a top-bottom symmetrical structure, all of the first, second, third, and fourth I/O driving modules may not have the symmetric signal characteristics.

As described above, when four I/O driving modules are arranged in the common-centroid structure according to example embodiments and when the common control logic circuit CCLC is placed in the empty space near the center, the semiconductor memory device may have advantages in terms of power, performance, and area (PPA).

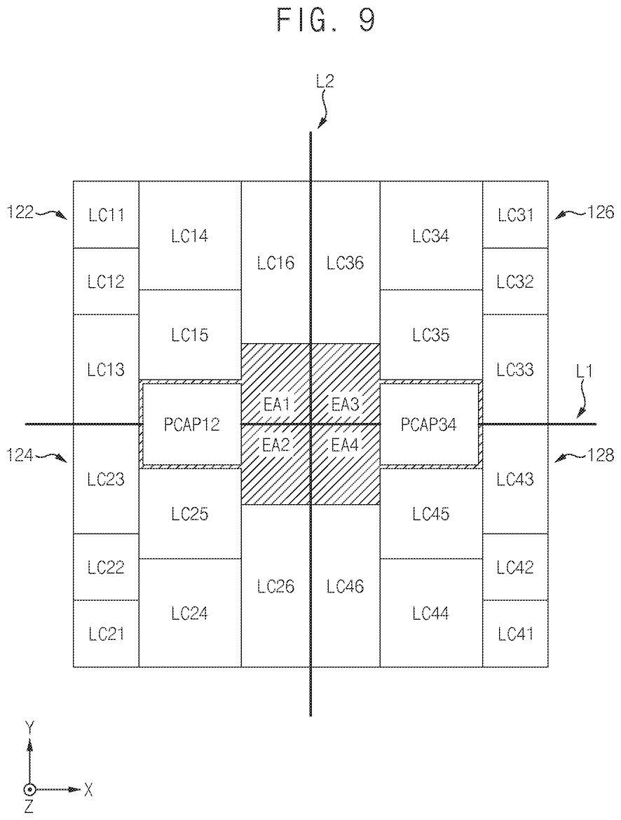

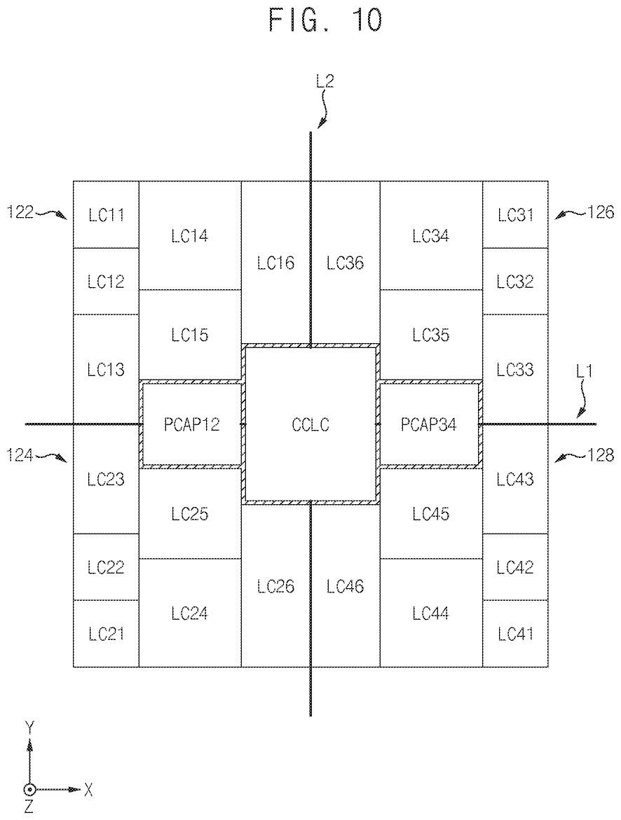

FIGS. 9 and 10 are diagrams illustrating examples of I/O driving module groups of FIGS. 3 and 5, respectively.

Referring to FIG. 9, an example of utilizing the first, second, third, and fourth empty spaces EA1, EA2, EA3, and EA4 in FIG. 6 is illustrated. The descriptions repeated with FIG. 6 will be omitted.

The semiconductor memory device according to example embodiments may further include power capacitors PCAP12 and PCAP34. The power capacitors PCAP12 and PCAP34 may be disposed in at least a portion of the first, second, third, and fourth empty spaces EA1, EA2, EA3, and EA4, and may perform a power stabilization function during an operation of the semiconductor memory device.

The power capacitor PCAP12 may be a component for the first and second I/O driving modules 122 and 124, and thus may be disposed to correspond to the first and second empty spaces EA1 and EA2. For example, the power capacitor PCAP12 may be disposed in the first and second empty spaces EA1 and EA2 of the first and second I/O driving modules 122 and 124. The power capacitor PCAP34 may be a component for the third and fourth I/O driving modules 126 and 128, and thus may be disposed to correspond to the third and fourth empty spaces EA3 and EA4. For example, the power capacitor PCAP34 may be disposed in the third and fourth empty spaces EA3 and EA4 of the third and fourth I/O driving modules 126 and 128. In some example embodiments, although not illustrated in FIG. 9, one power capacitor for all of the first, second, third, and fourth I/O driving modules 122, 124, 126, and 128 may be disposed to correspond to all of the first, second, third, and fourth empty spaces EA1, EA2, EA3, and EA4.

When the power capacitors PCAP12 and PCAP34 for two or more I/O driving modules are provided according to example embodiments, larger capacitance may be implemented with the same area and power capability performance may be improved, as compared with a case where each of four I/O driving modules has a power capacitor.

In some example embodiments, the power capacitors PCAP12 and PCAP34 may be replaced with other types of capacitors, e.g., capacitors that perform other functions. For example, rather than the power capacitors PCAP12 and PCAP34, signal capacitors may be disposed in at least a portion of the first, second, third, and fourth empty spaces EA1, EA2, EA3, and EA4. The signal capacitor may be a component for resolving the problem of excessive load on the semiconductor memory device during signal transmission. For example, the signal capacitor may be connected to a transmission path through which a signal is transmitted with relatively high power, and may perform a function of distributing the load.

Referring to FIG. 10, an example of utilizing the first, second, third, and fourth empty spaces EA1, EA2, EA3, and EA4 in FIG. 6 is illustrated. The descriptions repeated with FIGS. 6, 7 and 9 will be omitted.

The semiconductor memory device according to example embodiments may further include a common control logic circuit CCLC and power capacitors PCAP12 and PCAP34. FIG. 10 illustrates an example where the examples of FIGS. 7 and 9 are combined.

Although the examples where the common control logic circuit CCLC and/or the power capacitors PCAP12 and PCAP34, which are commonly used by the first, second, third, and fourth I/O driving modules 122, 124, 126, and 128, are disposed in the first, second, third, and fourth empty spaces EA1, EA2, EA3, and EA4 are described as an example where the first, second, third, and fourth empty spaces EA1, EA2, EA3, and EA4 are shared by the first, second, third, and fourth I/O driving modules 122, 124, 126, and 128, example embodiments are not limited thereto. For example, at least one of various components that are commonly used by the first, second, third, and fourth I/O driving modules 122, 124, 126, and 128, e.g., a power gating control circuit, a repeater circuit, etc., may be placed in the first, second, third, and fourth empty spaces EA1, EA2, EA3, and EA4.

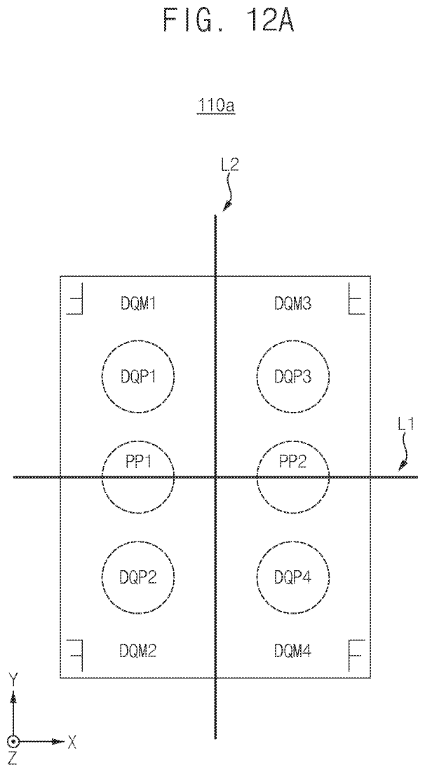

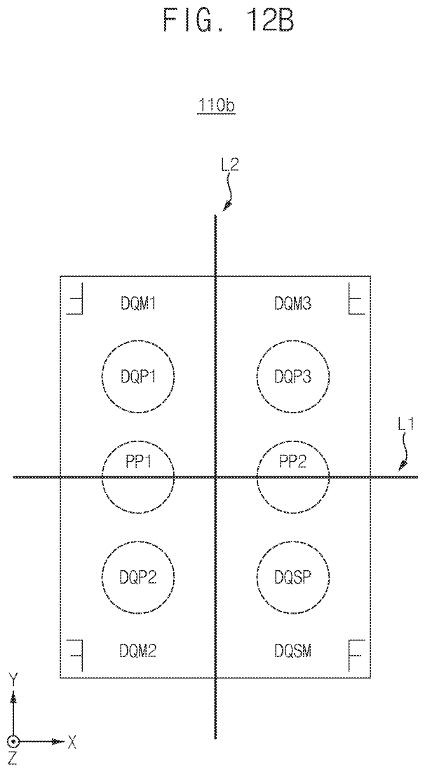

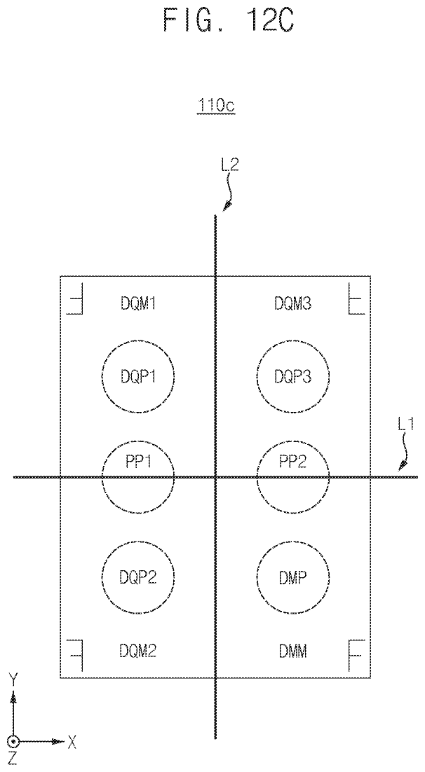

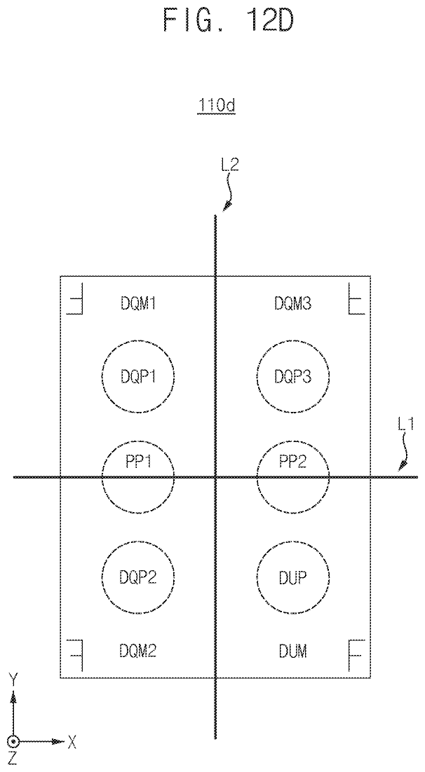

FIGS. 11A, 11B, 11C, 11D, 12A, 12B, 12C and 12D are diagrams illustrating examples of I/O driving module groups of FIGS. 3 and 5. The descriptions repeated with FIGS. 3 and 5 will be omitted.

Referring to FIG. 11A, an example of the I/O driving module group 100 of FIG. 3 is illustrated.

An I/O driving module group 100a may include a first data driving module DQM1 for driving a first data pad DQP1, a second data driving module DQM2 for driving a second data pad DQP2, a third data driving module DQM3 for driving a third data pad DQP3, and a fourth data driving module DQM4 for driving a fourth data pad DQP4. The first, second, third, and fourth data pads DQP1, DQP2, DQP3, and DQP4 may correspond to the first, second, third, and fourth I/O pads IOP1, IOP2, IOP3, and IOP4 in FIG. 3, respectively. The first, second, third, and fourth data driving modules DQM1, DQM2, DQM3, and DQM4 may correspond to the first, second, third, and fourth I/O driving modules IOM1, IOM2, IOM3, and IOM4 in FIG. 3, respectively. FIG. 11A illustrates an example where all of four I/O pads are data pads and all of four I/O driving modules are data driving modules.

Referring to FIG. 11B, an example of the I/O driving module group 100 of FIG. 3 is illustrated. The descriptions repeated with FIG. 11A will be omitted.

An I/O driving module group 100b may include a first data driving module DQM1 for driving a first data pad DQP1, a second data driving module DQM2 for driving a second data pad DQP2, a third data driving module DQM3 for driving a third data pad DQP3, and a data strobe driving module DQSM for driving a data strobe pad DQSP. A configuration of the data strobe driving module DQSM may be different from that of each of the data driving modules DQM1, DQM2, and DQM3. FIG. 11B illustrates an example where one data pad and one data driving module in the example of FIG. 11A are replaced with a data strobe pad and a data strobe driving module.

Referring to FIG. 11C, an example of the I/O driving module group 100 of FIG. 3 is illustrated. The descriptions repeated with FIG. 11A will be omitted.

An I/O driving module group 100c may include a first data driving module DQM1 for driving a first data pad DQP1, a second data driving module DQM2 for driving a second data pad DQP2, a third data driving module DQM3 for driving a third data pad DQP3, and a data mask driving module DMM for driving a data mask pad DMP. A configuration of the data mask driving module DMM may be similar to that of each of the data driving modules DQM1, DQM2, and DQM3. For example, as compared with the configuration of each of the data driving modules DQM1, DQM2, and DQM3, at least one logic circuit may be omitted in the data mask driving module DMM. FIG. 11C illustrates an example where one data pad and one data driving module in the example of FIG. 11A are replaced with a data mask pad and a data mask driving module.

Referring to FIG. 11D, an example of the I/O driving module group 100 of FIG. 3 is illustrated. The descriptions repeated with FIG. 11A will be omitted.

An I/O driving module group 100d may include a first data driving module DQM1 for driving a first data pad DQP1, a second data driving module DQM2 for driving a second data pad DQP2, a third data driving module DQM3 for driving a third data pad DQP3, and a dummy driving module DUM for driving a dummy pad DUP. A configuration of the dummy driving module DUM may be similar to that of each of the data driving modules DQM1, DQM2, and DQM3. For example, as compared with the configuration of each of the data driving modules DQM1, DQM2, and DQM3, at least one logic circuit may be omitted in the dummy driving module DUM. FIG. 11D illustrates an example where one data pad and one data driving module in the example of FIG. 11A are replaced with a dummy pad and a dummy driving module.

Referring to FIGS. 12A, 12B, 12C, and 12D, examples of the I/O driving module group 110 of FIG. 5 is illustrated. The descriptions repeated with FIGS. 11A, 11B, 11C, and 11D will be omitted.

As with the example of FIG. 11A, FIG. 12A illustrates an I/O driving module group 110a in which all of four I/O pads are data pads and all of four I/O driving modules are data driving modules.

As with the example of FIG. 11B, FIG. 12B illustrates an I/O driving module group 110b in which one data pad and one data driving module in the example of FIG. 12A are replaced with a data strobe pad and a data strobe driving module.

As with the example of FIG. 11C, FIG. 12C illustrates an I/O driving module group 110c in which one data pad and one data driving module in the example of FIG. 12A are replaced with a data mask pad and a data mask driving module.

As with the example of FIG. 11D, FIG. 12D illustrates an I/O driving module group 110d in which one data pad and one data driving module in the example of FIG. 12A are replaced with a dummy pad and a dummy driving module.

Although examples of configurations and arrangements of the I/O pads and the I/O driving modules are described with reference to FIGS. 11A, 11B, 11C, 11D, 12A, 12B, 12C, and 12D, example embodiments are not limited thereto, and types, configurations and arrangements of the I/O pads and I/O driving modules may be determined in various manners according to example embodiments.

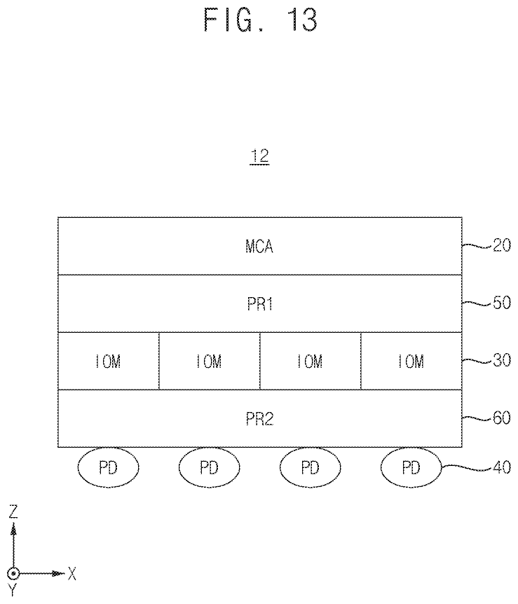

FIG. 13 is a cross-sectional view of a semiconductor memory device according to example embodiments. The descriptions repeated with FIG. 1 will be omitted.

Referring to FIG. 13, a semiconductor memory device 12 includes a memory cell array 20, a plurality of I/O driving modules 30, and a plurality of pads 40. The semiconductor memory device 12 may further include a first peripheral circuit (PR1) 50 and a second peripheral circuit (PR2) 60.

The first peripheral circuit 50 may be disposed between the memory cell array 20 and the plurality of I/O driving modules 30. The second peripheral circuit 60 may be disposed between the plurality of I/O driving modules 30 and the plurality of pads 40. For example, the first and second peripheral circuits 50 and 60 may be electrically connected to the memory cell array 20. For example, among peripheral circuits that control the operation of the memory cell array 20, the first and second peripheral circuits 50 and 60 may include some or all of the remaining components other than components included in the plurality of I/O driving modules 30.

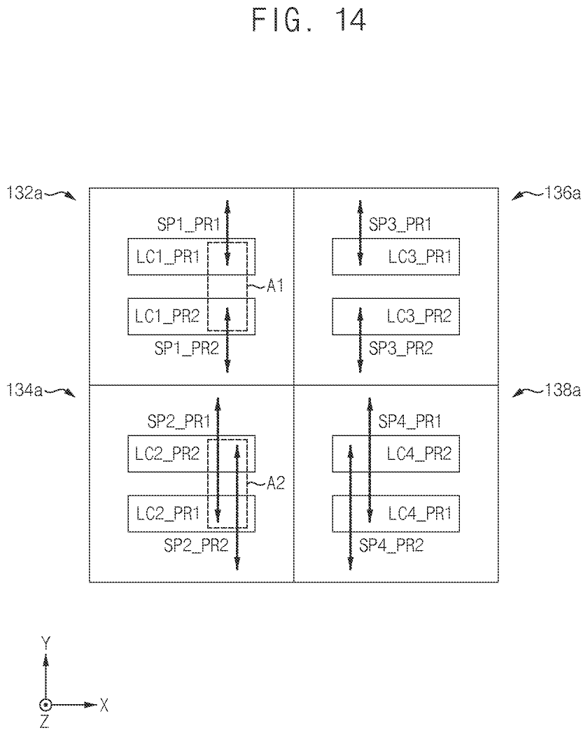

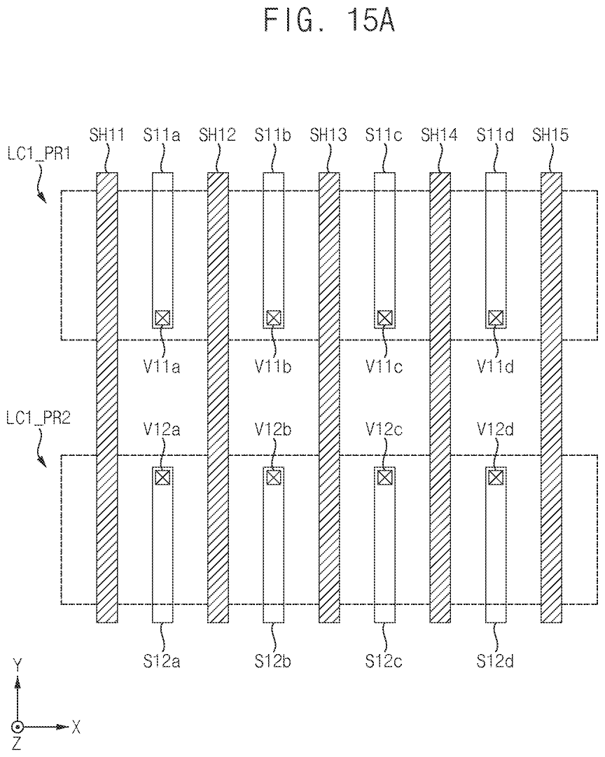

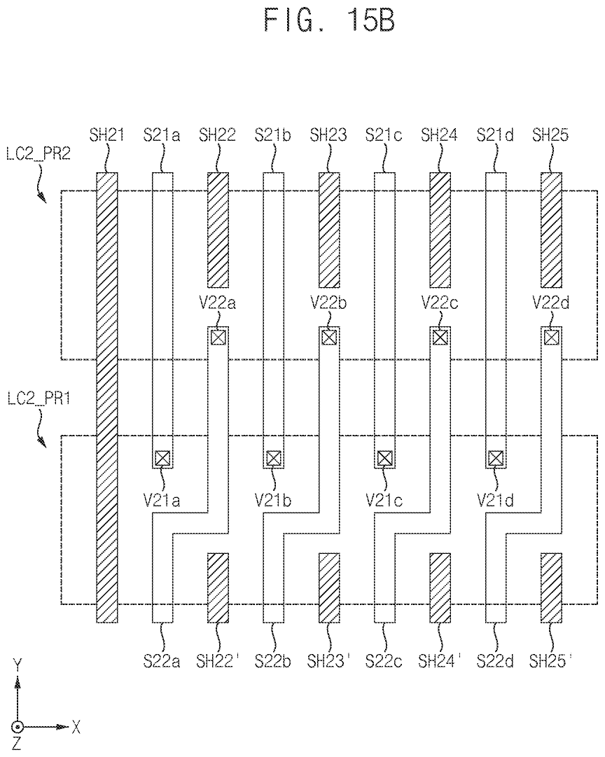

The plurality of I/O driving modules 30 may be electrically connected to the first and second peripheral circuits 50 and 60. Connection structures between the I/O driving modules 30 and the first and second peripheral circuits 50 and 60 may be implemented differently depending on a respective position of each of the plurality of I/O driving modules 30, which will be described with reference to FIGS. 14, 15A, and 15B.

FIGS. 14, 15A, and 15B are plan views of a semiconductor memory device according to example embodiments.

Referring to FIG. 14, an example of an arrangement and layout of a first I/O driving module 132a, a second I/O driving module 134a, a third I/O driving module 136a, and a fourth I/O driving module 138a, among the plurality of I/O driving modules IOM included in the semiconductor memory device 12 of FIG. 13, is illustrated on a plane.

The first I/O driving module 132a may include first logic circuits LC1_PR1 and LC1_PR2. The second I/O driving module 134a may include second logic circuits LC2_PR1 and LC2_PR2. The third I/O driving module 136a may include third logic circuits LC3_PR1 and LC3_PR2. The fourth I/O driving module 138a may include fourth logic circuits LC4_PR1 and LC4_PR2.

As described with reference to FIGS. 2 through 10, the first, second, third, and fourth input/output driving modules 132a, 134a, 136a, and 138a may have substantially the same structure/arrangement, may perform substantially the same function/operation, may be arranged in the common-centroid structure, and may share empty spaces near the center to have the advantages in terms of the PPA.

The first logic circuit LC1_PR1 included in the first I/O driving module 132a, the second logic circuit LC2_PR1 included in the second I/O driving module 134a, the third logic circuit LC3_PR1 included in the third I/O driving module 136a, and the fourth logic circuit LC4_PR1 included in the fourth I/O driving module 138a may be substantially the same circuit, and may be electrically connected to the first peripheral circuit 50 in FIG. 13. For example, the first logic circuit LC1_PR1 may be connected to the first peripheral circuit 50 through a signal path SP1_PR1 the second logic circuit LC2_PR1 may be connected to the first peripheral circuit 50 through a signal path SP2_PR1 the third logic circuit LC3_PR1 may be connected to the first peripheral circuit 50 through a signal path SP3_PR1 and the fourth logic circuit LC4_PR1 may be connected to the first peripheral circuit 50 through a signal path SP4_PR1.

The first logic circuit LC1_PR2 included in the first I/O driving module 132a, the second logic circuit LC2_PR2 included in the second I/O driving module 134a, the third logic circuit LC3_PR2 included in the third I/O driving module 136a, and the fourth logic circuit LC4_PR2 included in the fourth I/O driving module 138a may be substantially the same circuit, and may be electrically connected to the second peripheral circuit 60 in FIG. 13. For example, the first logic circuit LC1_PR2 may be connected to the second peripheral circuit 60 through a signal path SP1_PR2, the second logic circuit LC2_PR2 may be connected to the second peripheral circuit 60 through a signal path SP2_PR2, the third logic circuit LC3_PR2 may be connected to the second peripheral circuit 60 through a signal path SP3_PR2, and the fourth logic circuit LC4_PR2 may be connected to the second peripheral circuit 60 through a signal path SP4_PR2.

In some example embodiments, due to manufacturing process and/or design problems, there may be constraints or limitations associated with implementations of signal wires included in the signal paths SP1_PR1, SP1_PR2, SP2_PR1 SP2_PR2, SP3_PR1, SP3_PR2, SP4_PR1 and SP4_PR2. For example, signal wires included in the signal paths SP1_PR1 SP2_PR1 SP3_PR1 and SP4_PR1 for electrical connections to the first peripheral circuit 50 should extend only in an upward direction, e.g., in +Y-axis direction. For example, signal wires included in the signal paths SP1_PR2, SP2_PR2, SP3_PR2, and SP4_PR2 for electrical connections to the second peripheral circuit 60 should extend only in a downward direction, e.g., in a −Y-axis direction.

In some example embodiments, due to the above-described constraints, a configuration of signal wires for connecting the first logic circuits LC1_PR1 and LC1_PR2 with the first and second peripheral circuits 50 and 60 and a configuration of signal wires for connecting the second logic circuits LC2_PR1 and LC2_PR2 with the first and second peripheral circuits 50 and 60 may be different from each other.

For example, in the first I/O driving module 132a, the first logic circuit LC1_PR1 connected to the first peripheral circuit 50 may be disposed in an upper portion of the first I/O driving module 132a in a plan view, and the first logic circuit LC1_PR2 connected to the second peripheral circuit 60 may be disposed in a lower portion of the first I/O driving module 132a in a plan view. Thus, even if the signal wires included in the signal path SP1_PR1 for connecting the first peripheral circuit unit 50 with the first logic circuit LC1_PR1 extend in the upward direction, the signal wires included in the signal path SP1_PR1 may not pass through another first logic circuit LC1_PR2. Similarly, even if the signal wires included in the signal path SP1_PR2 for connecting the second peripheral circuit 60 with the first logic circuit LC1_PR2 extend in the downward direction, the signal wires included in the signal path SP1_PR2 may not pass through another first logic circuit LC1_PR1.

In contrast, in the second I/O driving module 134a disposed symmetrically to the first I/O driving module 132a, the second logic circuit LC2_PR1 connected to the first peripheral circuit 50 may be disposed in a lower portion of the second I/O driving module 134a in a plan view, and the second logic circuit LC2_PR2 connected to the second peripheral circuit 60 may be disposed in an upper portion of the first I/O driving module 132a in a plan view. In this case, when the signal wires included in the signal path SP2_PR1 for connecting the first peripheral circuit 50 with the second logic circuit LC2_PR1 extend in the upward direction, signal wires included in the signal path SP2_PR1 may pass through another second logic circuit LC2_PR2. Similarly, when the signal wires included in the signal path SP2_PR2 for connecting the second peripheral circuit 60 with the second logic circuit LC2_PR2 extend in the downward direction, signal wires included in the signal path SP2_PR2 may pass through another second logic circuit LC2_PR1.

Therefore, the configuration of the signal wires included in the signal paths SP1_PR1 and SP1_PR2 of the first I/O driving module 132a and the configuration of the signal wires included in the signal paths SP2_PR1 and SP2_PR2 of the second I/O driving module 134a may be implemented differently based on the above-described differences, and the signal wires may be efficiently implemented.

Similarly, a configuration of signal wires for connecting the third logic circuits LC3_PR1 and LC3_PR2 with the first and second peripheral circuits 50 and 60 and a configuration of signal wires for connecting the fourth logic circuits LC4_PR1 and LC4_PR2 with the first and second peripheral circuits 50 and 60 may be different from each other. However, the configuration of the signal wires for connecting the first logic circuits LC1_PR1 and LC1_PR2 with the first and second peripheral circuits 50 and 60 and the configuration of the signal wires for connecting the third logic circuits LC3_PR1 and LC3_PR2 with the first and second peripheral circuits 50 and 60 may be the same as each other, and the configuration of the signal wires for connecting the second logic circuits LC2_PR1 and LC2_PR2 with the first and second peripheral circuits 50 and 60 and the configuration of the signal wires for connecting the fourth logic circuits LC4_PR1 and LC4_PR2 with the first and second peripheral circuits 50 and 60 may be the same as each other.

Referring to FIG. 15A, an example of an area A1 in FIG. 14 is illustrated. For example, the configuration of the signal wires for connecting the first logic circuits LC1_PR1 and LC1_PR2 with the first and second peripheral circuits 50 and 60 may be disposed in the area A1.

Signal wires S11a, S11b, S11c, and Sild may electrically connect the first logic circuit LC1_PR1 with the first peripheral circuit 50. For example, the signal wires S11a, S11b, S11c, and Sild may be electrically connected to the first logic circuit LC1_PR1 by vias V11a, V11b, V11c, and V11d. Although not illustrated in detail, the signal wires S11a, S11b, S11c and S11d may extend in the upward direction, and may be electrically connected to the first peripheral circuit 50 by other vias.

Signal wires S12a, S12b, S12c, and S12d may electrically connect the first logic circuit LC1_PR2 with the second peripheral circuit 60. For example, the signal wires S12a, S12b, S12c, and S12d may be electrically connected to the first logic circuit LC1_PR2 by vias V12a, V12b, V12c, and V12d. Although not illustrated in detail, the signal wires S12a, S12b, S12c and S12d may extend in the downward direction, and may be electrically connected to the second peripheral circuit 60 by other vias.

The signal wires S11a, S11b, S11c, and S11d may not pass through the first logic circuit LC1_PR2, the signal wires S12a, S12b, S12c, and S12d may not pass through the first logic circuit LC1_PR1, and thus the signal wires S11a, S11b, S11c, and S11d and the signal wires S12a, S12b, S12c, and S12d may be entirely aligned along the second direction Y. For example, the signal wire S11a may be implemented as a straight line extending in the second direction Y, the signal line S12a may also be implemented as a straight line extending in the second direction Y, and such two straight lines may be disposed to be aligned along the second direction Y. Likewise, the signal wires 11b and 12b may be aligned with one another along the second direction Y, the signal wires 11c and 12c may be aligned with one another along the second direction Y, and the signal wires 11d and 12d may be aligned with one another along the second direction Y.

Shield wires SH11, SH12, SH13, SH14, and SH15 may be formed to protect the signal wires S11a, S11b, S11c, S11d, S12a, S12b, S12c, and S12d. For example, the shield wires SH11, SH12, SH13, SH14, and SH15 and the signal wires S11a, S11b, S11c, S11d, S12a, S12b, S12c, and S12d may be formed or arranged alternately, and at least one signal wire may be formed or disposed between two adjacent shield wires. For example, the signal wires S11a and S12a may be formed between the shield wires SH11 and SH12. Likewise, the signal wires S11b and S12b may be formed between the shield wires SH12 and SH13, the signal wires S11c and S12c may be formed between the shield wires SH13 and SH14, and the signal wires S11d and S12d may be formed between the shield wires SH14 and SH15.

In an example of FIG. 15A where the signal wires do not pass through an area in which the logic circuit unconnected to the signal wires is disposed, the signal wires may be implemented relatively simply, and the shield wires SH11, SH12, SH13, SH14, and SH15 may be formed to extend throughout without being cut off. For example, when the signal wires S11a and S12a are to be formed, one straight wire pattern may be formed, and then a middle portion of the straight wire pattern may be removed, so that two aligned signal wires S11a and S12a may be provided. In addition, while an operation of the signal wires S11a, S11b, S11c, and S11d and/or an operation of the signal wires S12a, S12b, S12c, and S12d, a shielding effect may be achieved by the shield wires SH11, SH12, SH13, SH14, and SH15.

Referring to FIG. 15B, an example of an area A2 in FIG. 14 is illustrated. For example, the configuration of the signal wires for connecting the second logic circuits LC2_PR1 and LC2_PR2 with the first and second peripheral circuits 50 and 60 may be disposed in the area A2.

Signal wires S21a, S21b, S21c, and S21d may electrically connect the second logic circuit LC2_PR1 with the first peripheral circuit 50. For example, the signal wires S21a, S21b, S21c, and S21d may be electrically connected to the first logic circuit LC1_PR1 by vias V21a, V21b, V21c, and V21d. Although not illustrated in detail, the signal wires S21a, S21b, S21c, and S21d may extend in the upward direction, and may be electrically connected to the first peripheral circuit 50 by other vias.

Signal wires S22a, S22b, S22c, and S22d may electrically connect the second logic circuit LC2_PR2 with the second peripheral circuit 60. For example, the signal wires S22a, S22b, S22c, and S22d may be electrically connected to the second logic circuit LC2_PR2 by vias V22a, V22b, V22c, and V22d. Although not illustrated in detail, the signal wires S22a, S22b, S22c and S22d may extend in the downward direction, and may be electrically connected to the second peripheral circuit 60 by other vias.

The signal wires S21a, S21b, S21c, and S21d may pass through the second logic circuit LC2_PR2, the signal wires S22a, S22b, S22c, and S22d may pass through the second logic circuit LC2_PR1, and thus the signal wires S21a, S21b, S21c, and S21d and the signal wires S22a, S22b, S22c, and S22d may be partially aligned along the second direction Y and may not be partially aligned (e.g., partially unaligned) along the second direction Y. For example, the signal wire S21a may be implemented as a straight line extending in the second direction Y, the signal wire S22a may be implemented as a polygonal line (or broken line) including first and second portions extending in the second direction Y and a third portion extending in the first direction X and connecting the first and second portions. The signal wire S21a may be aligned with the first portion of the signal wire S22a extending in the second direction Y, and may not be aligned with the second portion of the signal wire S22a extending in the second direction Y and the third portion of the signal wire S22a extending in the first direction X.

As with the example of FIG. 15A, shield wires SH21, SH22, SH22′, SH23, SH23′, SH24, SH24′, SH25, and SH25′ may be formed to protect the signal wires S21a, S21b, S21c, S21d, S22a, S22b, S22c, and S22d.

In an example of FIG. 15B where the signal wires pass through an area in which the logic circuit unconnected to the signal wires is disposed, the signal wires may be implemented by utilizing a portion of the shield wires, without additional lines. For example, when the signal wires S21a and S22a and the shield wires SH22 and SH22′ are to be formed, two straight wire patterns may be formed to be parallel to each other, middle portions of the two straight wire patterns may be removed for forming the signal wire S21a and the first and second portions of the signal wire S22a, and then the third portion of the signal wire S22a may be formed for connecting the first and second portions of the signal wire S22a, so that two signal wires S21a and S22a may be provided. The remaining portions of the two straight wire patterns may be provided as the shield wires SH22 and SH22′.

In some example embodiments, an operation of the signal wires S21a, S21b, S21c, and S21d and an operation of the signal wires S22a, S22b, S22c, and S22d may not be performed simultaneously, and may be performed alternately. For example, while the operation of the signal wires S21a, S21b, S21c, and S21d, the signal wires S22a, S22b, S22c, and S22d may not operate or may not be driven, and a shielding effect may be achieved by the shield wires SH21, SH22, SH22′, SH23, SH23′, SH24, SH24′, SH25, and SH25′ and the signal wires S22a, S22b, S22c, and S22d. Similarly, while the operation of the signal wires S22a, S22b, S22c, and S22d the signal wires S21a, S21b, S21c, and S21d may not operate or may not be driven, and a shielding effect may be achieved by the shield wires SH21, SH22, SH22′, SH23, SH23′, SH24, SH24′, SH25, and SH25′ and the signal wires S21a, S21b, S21c, and S21d.

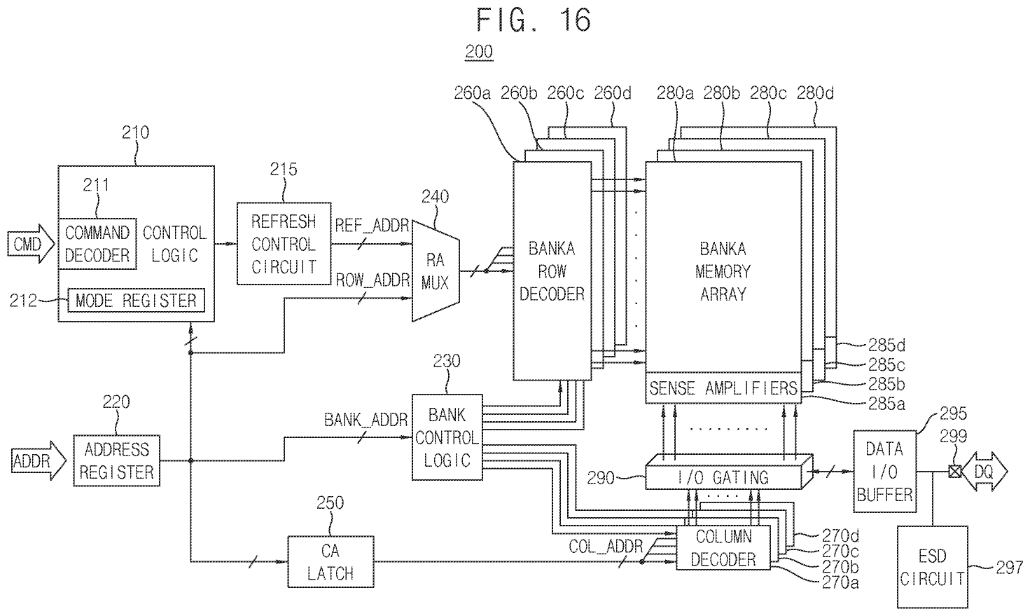

FIG. 16 is a block diagram illustrating an example of a semiconductor memory device according to example embodiments.

Referring to FIG. 16, a semiconductor memory device 200 includes a control logic 210, a refresh control circuit 215, an address register 220, a bank control logic 230, a row address multiplexer 240, a column address latch 250, a row decoder, a column decoder, a memory cell array, a sense amplifier unit, an input/output (I/O) gating circuit 290, a data I/O buffer 295, an electrostatic discharge (ESD) protection circuit 297, and a data I/O pad 299. For example, the semiconductor memory device 200 may be one of various volatile memory devices such as a dynamic random access memory (DRAM).

The memory cell array may include a plurality of memory cells. The memory cell array may include a plurality of bank arrays, e.g., first to fourth bank arrays 280a, 280b, 280c, and 280d. The row decoder may include a plurality of bank row decoders, e.g., first to fourth bank row decoders 260a, 260b, 260c, and 260d connected to the first to fourth bank arrays 280a, 280b, 280c, and 280d, respectively. The column decoder may include a plurality of bank column decoders, e.g., first to fourth bank column decoders 270a, 270b, 270c, and 270d connected to the first to fourth bank arrays 280a, 280b, 280c, and 280d, respectively. The sense amplifier unit may include a plurality of bank sense amplifiers, e.g., first to fourth bank sense amplifiers 285a, 285b, 285c, and 285d connected to the first to fourth bank arrays 280a, 280b, 280c, and 280d, respectively.

The first to fourth bank arrays 280a to 280d, the first to fourth bank row decoders 260a to 260d, the first to fourth bank column decoders 270a to 270d, and the first to fourth bank sense amplifiers 285a to 285d may form first to fourth banks, respectively. For example, the first bank array 280a, the first bank row decoder 260a, the first bank column decoder 270a, and the first bank sense amplifier 285a may form the first bank; the second bank array 280b, the second bank row decoder 260b, the second bank column decoder 270b, and the second bank sense amplifier 285b may form the second bank; the third bank array 280c, the third bank row decoder 260c, the third bank column decoder 270c, and the third bank sense amplifier 285c may form the third bank; and the fourth bank array 280d, the fourth bank row decoder 260d, the fourth bank column decoder 270d, and the fourth bank sense amplifier 285d may form the fourth bank.

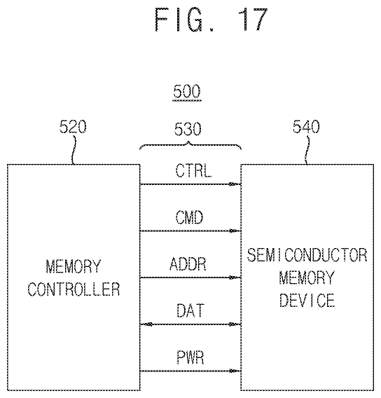

The address register 220 may receive an address ADDR including a bank address BANK_ADDR, a row address ROW_ADDR, and a column address COL_ADDR from a memory controller (e.g., from memory controller 520 in FIG. 17) located outside the semiconductor memory device 200. The address register 220 may provide the received bank address BANK_ADDR to the bank control logic 230, may provide the received row address ROW_ADDR to the row address multiplexer 240, and may provide the received column address COL_ADDR to the column address latch 250.

The bank control logic 230 may generate bank control signals in response to receipt of the bank address BANK_ADDR. One of the first to fourth bank row decoders 260a to 260d corresponding to the received bank address BANK_ADDR may be activated in response to the bank control signals generated by the bank control logic 230, and one of the first to fourth bank column decoders 270a to 270d corresponding to the received bank address BANK_ADDR may be activated in response to the bank control signals generated by the bank control logic 230.

The refresh control circuit 215 may generate a refresh address REF_ADDR in response to receipt of a refresh command or entrance of any self-refresh mode. For example, the refresh control circuit 215 may include a refresh counter that is configured to sequentially change the refresh address REF_ADDR from a first address of the memory cell array to a last address of the memory cell array. The refresh control circuit 215 may receive control signals from the control logic 210.

The row address multiplexer 240 may receive the row address ROW_ADDR from the address register 220, and may receive the refresh address REF_ADDR from the refresh control circuit 215. The row address multiplexer 240 may selectively output the row address ROW_ADDR or the refresh address REF_ADDR. A row address (e.g., the row address ROW_ADDR or the refresh address REF_ADDR) output from the row address multiplexer 240 may be applied to the first to fourth bank row decoders 260a to 260d.

The activated one of the first to fourth bank row decoders 260a to 260d may decode the row address output from the row address multiplexer 240, and may activate a wordline corresponding to the row address. For example, the activated bank row decoder may apply a wordline driving voltage to the wordline corresponding to the row address.

The column address latch 250 may receive the column address COL_ADDR from the address register 220, and may temporarily store the received column address COL_ADDR. The column address latch 250 may apply the temporarily stored or received column address COL_ADDR to the first to fourth bank column decoders 270a to 270d.

The activated one of the first to fourth bank column decoders 270a to 270d may decode the column address COL_ADDR output from the column address latch 250, and may control the I/O gating circuit 290 to output data corresponding to the column address COL_ADDR.

The I/O gating circuit 290 may include a circuitry for gating I/O data. For example, although not shown, the I/O gating circuit 290 may include an input data mask logic, read data latches for storing data output from the first to fourth bank arrays 280a to 280d, and write drivers for writing data to the first to fourth bank arrays 280a to 280d.

Data DQ to be read from one of the first to fourth bank arrays 280a to 280d may be sensed by a sense amplifier coupled to the one of the first to fourth bank arrays 280a to 280d, and may be stored in the read data latches. The data DQ stored in the read data latches may be provided to the memory controller via the data I/O buffer 295 and the data I/O pad 299. Data DQ received via the data I/O pad 299 that are to be written to one of the first to fourth bank arrays 280a to 280d may be provided from the memory controller to the data I/O buffer 295. The data DQ received via the data I/O pad 299 and provided to the data I/O buffer 295 may be written to the one bank array via the write drivers in the I/O gating circuit 290.

The control logic 210 may control an operation of the semiconductor memory device 200. For example, the control logic 210 may generate control signals for the semiconductor memory device 200 to perform a data write operation or a data read operation. The control logic 210 may include a command decoder 211 that decodes a command CMD received from the memory controller and a mode register 212 that sets an operation mode of the semiconductor memory device 200. For example, the command decoder 211 may generate the control signals corresponding to the command CMD by decoding a write enable signal (e.g., /WE), a row address strobe signal (e.g., /RAS), a column address strobe signal (e.g., /CAS), a chip select signal (e.g., /CS), etc. The control logic 210 may further receive a clock signal (e.g., CLK) and a clock enable signal (e.g., /CKE) for operating the semiconductor memory device 200 in a synchronous scheme.

In some example embodiments, the data I/O buffer 295, the ESD protection circuit 297, or the like, may be included in the I/O driving module 30 in FIG. 1. In some example embodiments, the control logic 210, the refresh control circuit 215, the address register 220, the bank control logic 230, the row address multiplexer 240, the column address latch 250, the row decoder, the column decoder, the sense amplifier unit, the I/O gating circuit 290, or the like, may be included in the first and second peripheral circuits 50 and 60 in FIG. 13.

Although the semiconductor memory device according to example embodiments is described based on a DRAM, the semiconductor memory device according to example embodiments may be any volatile memory device and/or any nonvolatile memory device, e.g., a static random access memory (SRAM), a flash memory, a phase-change random access memory (PRAM), a resistive random access memory (RRAM), a nano floating gate memory (NFGM), a polymer random access memory (PoRAM), a magnetic random access memory (MRAM), a ferroelectric random access memory (FRAM), a thyristor random access memory (TRAM), etc.

FIG. 17 is a block diagram illustrating a memory system including a semiconductor memory device according to example embodiments.

Referring to FIG. 17, a memory system 500 includes a memory controller 520 and a semiconductor memory device 540. The memory system 500 may further include a plurality of signal lines 530 that electrically connect the memory controller 520 with the semiconductor memory device 540.

The semiconductor memory device 540 is controlled by the memory controller 520. For example, based on requests from a host (not illustrated), the memory controller 520 may store (e.g., write or program) data into the semiconductor memory device 540, or may retrieve (e.g., read or sense) data from the semiconductor memory device 540.

The plurality of signal lines 530 may include control lines, command lines, address lines, data input/output (I/O) lines and power lines. The memory controller 520 may transmit a command CMD, an address ADDR and a control signal CTRL to the semiconductor memory device 540 via the command lines, the address lines, and the control lines, may exchange a data signal DAT with the semiconductor memory device 540 via the data I/O lines, and may transmit a power supply voltage PWR to the semiconductor memory device 540 via the power lines. Although not illustrated in FIG. 17, the plurality of signal lines 530 may further include data strobe signal (DQS) lines for transmitting a DQS signal.

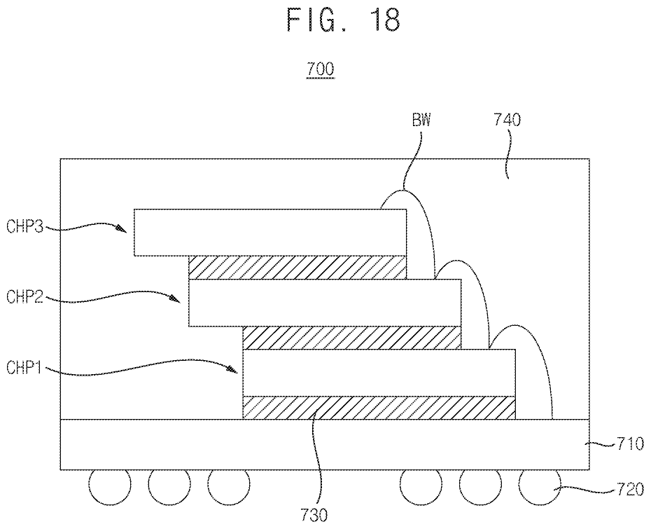

FIGS. 18, 19, and 20 are diagrams illustrating a semiconductor package according to example embodiments.

Referring to FIG. 18, a semiconductor package 700 includes a base substrate 710, and a plurality of memory chips CHP1, CHP2, and CHP3 stacked on the base substrate 710.

Each of the memory chips CHP1 to CHP3 may include the semiconductor memory device according to example embodiments.

In some example embodiments, the memory chips CHP1 to CHP3 may be stacked on the base substrate 710 such that a surface on each of the memory chips CHP1 to CHP3 on which I/O pads are formed faces upwards. In some example embodiments, with respect to each of the memory chips CHP1 to CHP3, the I/O pads may be arranged near one side of the semiconductor substrate. As such, the memory chips CHP1 to CHP3 may be stacked scalariformly, that is, in a step shape, such that the I/O pads of each memory chip may be exposed. In such stacked state, the memory chips CHP1 to CHP3 may be electrically connected to the base substrate 710 through a plurality of bonding wires BW.

The stacked memory chips CHP1 to CHP3 and the plurality of bonding wires BW may be fixed by a sealing member 740, and adhesive members 730 may intervene between the base substrate 710 and the memory chips CHP1 to CHP3. Conductive bumps 720 may be formed on a bottom surface of the base substrate 710 for electrical connections to an external device.

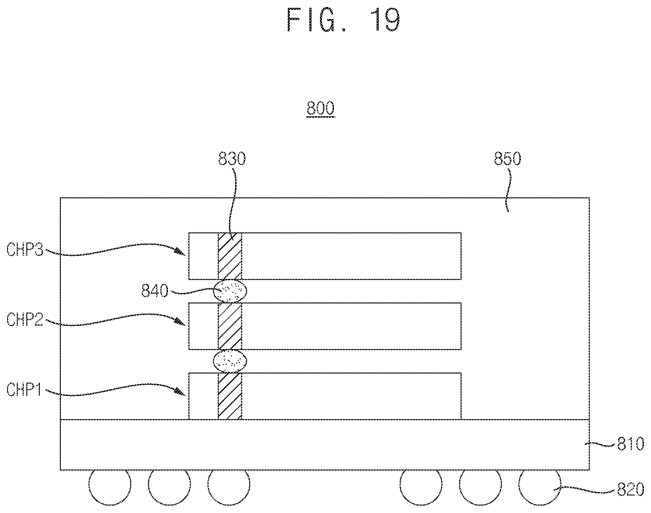

Referring to FIG. 19, a semiconductor package 800 includes a base substrate 810, and a plurality of memory chips CHP1, CHP2, and CHP3 stacked on the base substrate 810. The descriptions repeated with FIG. 18 will be omitted.

Each of the memory chips CHP1 to CHP3 may further include a plurality of through silicon vias (TSVs) 830.

In some example embodiments, with respect to each of the memory chips CHP1 to CHP3, the plurality of TSVs 830 may be arranged at the same locations in each memory chip. As such, the memory chips CHP1 to CHP3 may be stacked such that the plurality of TSVs 830 of each memory chip may be completely overlapped (e.g., arrangements of the plurality of TSVs 830 may be perfectly matched in the memory chips CHP1 to CHP3). In such stacked state, the memory chips CHP1 to CHP3 may be electrically connected to one another and the base substrate 810 through the plurality of TSVs 830 and conductive material 840. The conductive material 840 may be disposed between TSVs 830 of the memory chips CHP1 and CHP2, and may contact the TSVs 830 of the memory chips CHP1 and CHP2. In addition, the conductive material 840 may be disposed between TSVs 830 of the memory chips CHP2 and CHP3, and may contact the TSVs 830 of the memory chips CHP2 and CHP3.

Conductive bumps 820 and a sealing member 850 may be substantially the same as the conductive bumps 720 and the sealing member 740, respectively, in FIG. 18.

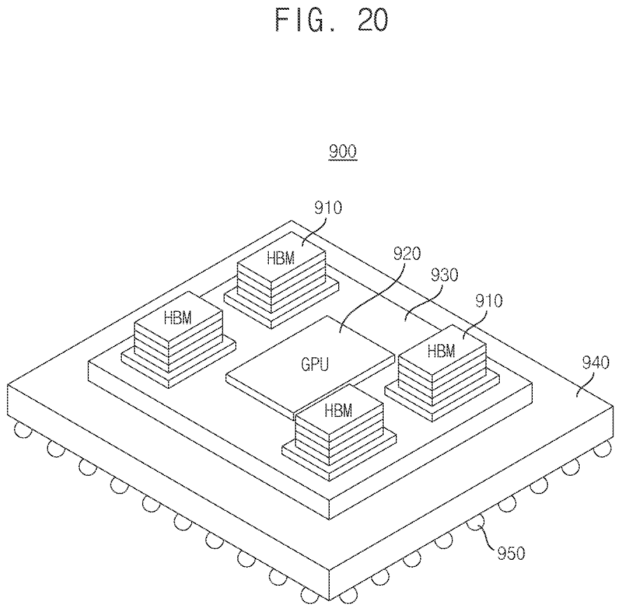

Referring to FIG. 20, a semiconductor package 900 includes one or more stacked memory devices 910 and a processing device 920. For example, the processing device 920 may be a graphic processing unit (GPU).

The stacked memory devices 910 and the processing device 920 may be mounted on an interposer 930, and the interposer 930 on which the stacked memory devices 910 and the processing device 920 are mounted may be mounted on a package substrate 940 mounted on solder balls 950. The processing device 920 may correspond to a semiconductor device which may perform a memory control function, and for example, the processing device 920 may be implemented as an application processor (AP) or one of various processors.

The stacked memory devices 910 may be implemented in various forms, and the stacked memory devices 910 may be a memory device in a high bandwidth memory (HBM) form in which a plurality of layers are stacked. Accordingly, the stacked memory devices 910 may be implemented by stacking the plurality of memory chips including the semiconductor memory devices according to example embodiments, as described with reference to FIGS. 18 and 19.

The plurality of stacked memory devices 910 may be mounted on the interposer 930, and the processing device 920 may communicate with the plurality of stacked memory devices 910. For example, each of the stacked memory devices 910 and the processing device 920 may include a physical region, and communication may be performed between the stacked memory devices 910 and the processing device 920 through the physical regions. For example, when the stacked memory devices 910 include a direct access region, a signal may be provided into the stacked memory devices 910 through conductive means (e.g., the solder balls 950) mounted under the package substrate 940 and the direct access region.

The example embodiments may be applied to various electronic devices and systems that include the semiconductor memory devices. For example, the example embodiments may be applied to systems such as a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IoT) device, an internet of everything (IoE) device, an e-book reader, a virtual reality (VR) device, an augmented reality (AR) device, a robotic device, a drone, an automotive, etc.

The foregoing is illustrative of example embodiments and is not to be construed as limiting thereof. Although some example embodiments have been described, those skilled in the art will readily appreciate that many modifications are possible in the example embodiments without materially departing from the novel teachings and advantages of the example embodiments. Accordingly, all such modifications are intended to be included within the scope of the example embodiments as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A semiconductor memory device comprising:
a memory cell array;
first, second, third, and fourth input/output (I/O) pads under the memory cell array, and configured to electrically connect the memory cell array with an external device; and
first, second, third, and fourth I/O driving modules between the memory cell array and the first, second, third, and fourth I/O pads, and configured to drive the first, second, third, and fourth I/O pads, respectively, and
wherein, in a plan view, the first and second I/O driving modules are disposed symmetrically with respect to a first line extending in a first direction, the third and fourth I/O driving modules are disposed symmetrically with respect to the first line, the first and third I/O driving modules are disposed symmetrically with respect to a second line extending in a second direction crossing the first direction, and the second and fourth I/O driving modules are disposed symmetrically with respect to the second line.

2. The semiconductor memory device of claim 1, wherein:
in the plan view, the first and third I/O pads are arranged along the first direction, the second and fourth I/O pads are arranged along the first direction, the first and second I/O pads are arranged along the second direction, and the third and fourth I/O pads are arranged along the second direction, and
the first, second, third, and fourth I/O driving modules overlap the first, second, third, and fourth I/O pads, respectively.

3. The semiconductor memory device of claim 2, wherein:
the first line is between the first and second I/O pads and between the third and fourth I/O pads, and
the first line is between the first and third I/O pads and between the second and fourth I/O pads.

4. The semiconductor memory device of claim 2, further comprising:
first and second power pads under the memory cell array, and configured to provide a power supply voltage and a ground voltage, and
wherein, in the plan view, the first power pad is between the first I/O pad and the second I/O pad, and the second power pad is between the third I/O pad and the fourth I/O pad.

5. The semiconductor memory device of claim 4, wherein:
in the plan view, the first and second power pads are arranged along the first direction, the first I/O pad, the first power pad, and the second I/O pad are arranged along the second direction, and the third I/O pad, the second power pad, and the fourth I/O pad are arranged along the second direction, and
the first I/O driving module overlaps the first I/O pad and a first portion of the first power pad, the second I/O driving module overlaps the second I/O pad and a second portion of the first power pad, the third I/O driving module overlaps the third I/O pad and a first portion of the second power pad, and the fourth I/O driving module overlaps the fourth I/O pad and a second portion of the second power pad.

6. The semiconductor memory device of claim 5, wherein the second line passes through the first and second power pads.

7. The semiconductor memory device of claim 1, wherein:
the first, second, third and fourth I/O driving modules include first, second, third, and fourth logic circuits, respectively, and
in the plan view, an arrangement of the first logic circuits and an arrangement of the second logic circuits are symmetrical with respect to the first line, an arrangement of the third logic circuits and an arrangement of the fourth logic circuits are symmetrical with respect to the first line, the arrangement of the first logic circuits and the arrangement of the third logic circuits are symmetrical with respect to the second line, and the arrangement of the second logic circuits and the arrangement of the fourth logic circuits are symmetrical with respect to the second line.

8. The semiconductor memory device of claim 7, wherein:
the first, second, third and fourth I/O driving modules include first, second, third and fourth empty spaces, respectively, in which the first, second, third and fourth logic circuits are not disposed, and
the first to fourth empty spaces are shared by the first to fourth I/O driving modules.

9. The semiconductor memory device of claim 8, wherein the first to fourth empty spaces are adjacent to the first and second lines.

10. The semiconductor memory device of claim 8, further comprising:
a common control logic circuit in at least a portion of the first to fourth empty spaces, and configured to control the first to fourth logic circuits.

11. The semiconductor memory device of claim 10, wherein the common control logic circuit is disposed to correspond to an intersection of the first and second lines, and is disposed to correspond to all of the first to fourth empty spaces.

12. The semiconductor memory device of claim 10, wherein:
a first signal path is from the common control logic circuit to a first destination logic circuit among the first logic circuits, a second signal path is from the common control logic circuit to a second destination logic circuit among the second logic circuits, a third signal path is from the common control logic circuit to a third destination logic circuit among the third logic circuits, and a fourth signal path is from the common control logic circuit to a fourth destination logic circuit among the fourth logic circuits, and
a length of the first signal path, a length of the second signal path, a length of the third signal path, and a length of the fourth signal path are equal to each other.

13. The semiconductor memory device of claim 8, further comprising:
a power capacitor in at least a portion of the first to fourth empty spaces.

14. The semiconductor memory device of claim 7, further comprising:
a first peripheral circuit between the memory cell array and the first to fourth I/O driving modules; and
a second peripheral circuit between the first to fourth I/O driving modules and the first to fourth I/O pads,
wherein a configuration of signal wires connecting the first logic circuits with the first and second peripheral circuits and a configuration of signal wires connecting the second logic circuits with the first and second peripheral circuits are different from each other.

15. The semiconductor memory device of claim 14, wherein:
the first logic circuits include a first-first logic circuit connected to the first peripheral circuit, and a first-second logic circuit connected to the second peripheral circuit, and
first signal wires electrically connecting the first peripheral circuit with the first-first logic circuit and second signal wires electrically connecting the second peripheral circuit with the first-second logic circuit are entirely aligned along the second direction.

16. The semiconductor memory device of claim 14, wherein:
the second logic circuits include a second-first logic circuit connected to the first peripheral circuit, and a second-second logic circuit connected to the second peripheral circuit, and
first signal wires electrically connecting the first peripheral circuit with the second-first logic circuit and second signal wires electrically connecting the second peripheral circuit with the second-second logic circuit are partially aligned along the second direction and are partially unaligned along the second direction.

17. The semiconductor memory device of claim 1, wherein each of the first to fourth I/O pads is one of a data pad, a data strobe pad, a data mask pad, and a dummy pad.

18. A semiconductor package comprising:
a plurality of semiconductor memory devices sequentially stacked in a vertical direction,
wherein each of the plurality of semiconductor memory devices comprises:
a memory cell array;
first, second, third, and fourth input/output (I/O) pads under the memory cell array, and configured to electrically connect the memory cell array with an external device; and
first, second, third, and fourth I/O driving modules between the memory cell array and the first, second, third and fourth I/O pads, and configured to drive the first, second, third and fourth I/O pads, respectively, and
wherein, in a plan view, the first and second I/O driving modules are disposed symmetrically with respect to a first line extending in a first direction, the third and fourth I/O driving modules are disposed symmetrically with respect to the first line, the first and third I/O driving modules are disposed symmetrically with respect to a second line extending in a second direction crossing the first direction, and the second and fourth I/O driving modules are disposed symmetrically with respect to the second line.

19. The semiconductor package of claim 18, further comprising:
a processing device configured to control the plurality of semiconductor memory devices; and
an interposer on which the plurality of semiconductor memory devices and the processing device are mounted.

20. A semiconductor package comprising:
a memory cell array;
first, second, third, and fourth input/output (I/O) pads under the memory cell array, and configured to electrically connect the memory cell array with an external device;
first and second power pads under the memory cell array, and configured to provide a power supply voltage and a ground voltage; and
first, second, third, and fourth I/O driving modules between the memory cell array and the first to fourth I/O pads and between the memory cell array and the first and second power pads, and configured to drive the first, second, third, and fourth I/O pads, respectively,
wherein, in a plan view, the first and second I/O driving modules are disposed symmetrically with respect to a first line extending in a first direction, the third and fourth I/O driving modules are disposed symmetrically with respect to the first line, the first and third I/O driving modules are disposed symmetrically with respect to a second line extending in a second direction crossing the first direction, and the second and fourth I/O driving modules are disposed symmetrically with respect to the second line,
wherein, in the plan view, the first and third I/O pads are arranged along the first direction, the first and second power pads are arranged along the first direction, the second and fourth I/O pads are arranged along the first direction, the first I/O pad, the first power pad, and the second I/O pad are arranged along the second direction, and the third I/O pad, the second power pad, and the fourth I/O pad are arranged along the second direction,
wherein the first I/O driving module overlaps the first I/O pad and a first portion of the first power pad, the second I/O driving module overlaps the second I/O pad and a second portion of the first power pad, the third I/O driving module overlaps the third I/O pad and a first portion of the second power pad, and the fourth I/O driving module overlaps the fourth I/O pad and a second portion of the second power pad,
wherein the first, second, third, and fourth I/O driving modules include first, second, third, and fourth logic circuits, respectively,
wherein the first, second, third, and fourth I/O driving modules include first, second, third, and fourth empty spaces, respectively, in which the first, second, third, and fourth logic circuits are not disposed,
wherein the first to fourth empty spaces are adjacent to the first and second lines, and
wherein the first to fourth empty spaces are shared by the first to fourth I/O driving modules.
